(19) United States
(12) Patent Application Publication
(10) Pub. No.: US 2025/0354278 A1
(43) Pub. Date: Nov. 20, 2025

(54) ELECTROCHEMICAL WATER SPLITTING WITH A NIVOX CATALYST

(71) Applicant: KING FAHD UNIVERSITY OF PETROLEUM AND MINERALS, Dhahran (SA)

(72) Inventors: Muhammad Ali EHSAN, Dhahran (SA); Abbas Saeed HAKEEM, Dhahran (SA)

(73) Assignee: KING FAHD UNIVERSITY OF PETROLEUM AND MINERALS, Dhahran (SA)

(21) Appl. No.: 19/284,010

(22) Filed: Jul. 29, 2025

Related U.S. Application Data
(62) Division of application No. 17/876,215, filed on Jul. 28, 2022.

(51) Int. Cl. C25B 11/077; C23C 16/04; C23C 16/40; C23C 16/448; C25B 1/04; C25B 11/031; C25B 11/052; C25B 11/061

(52) U.S. Cl. CPC C25B 11/077; C23C 16/045; C23C 16/405; C23C 16/4486; C25B 1/04; C25B 11/031; C25B 11/052; C25B 11/061

(57) ABSTRACT

An electrocatalyst and a method of preparing the electrocatalyst are described. The electrocatalyst includes a porous foam substrate; and a catalytically active layer comprising NiVOx nanostructures, the catalytically active layer being disposed on an exterior surface and an interior pore surface of the porous metal foam substrate; where “x” is in the range of 1 to 3. A method of using the electrocatalyst for water oxidation is also described.

### BACKGROUND

### Technical Field

The present disclosure is directed to electrocatalysts, particularly NiVOx electrocatalysts for electrochemical water oxidation and methods of preparation thereof.

### Description of Related Art

The “background” description provided herein is to present the context of the disclosure generally. Work of the presently named inventors, to the extent it is described in this background section, and aspects of the description that may not otherwise qualify as prior art at the time of filing, are neither expressly nor impliedly admitted as prior art against the present invention.

Existing non-renewable, exhaustible energy resources are a considerable risk to the living environment. The enormous amount of CO₂ in the atmosphere (surpassing 400 ppm) has become a major global problem that needs to be addressed by developing and employing sustainable and renewable energy alternative energy sources such as hydrogen. High-energy-density, CO₂-neutral, and eco-friendly hydrogen-based fuels can potentially serve as a versatile feedstock for the synthesis of valuable chemicals. In this regard, hydrogen, obtained from a photoelectrochemical and electrochemical water splitting process, is the only clean and economically viable energy source that is green and with zero emission. In addition, the abundant water supply ensures the sustainable production of hydrogen over long periods.

Electrochemical water splitting occurs in two reaction steps: the hydrogen evolution reaction (HER) and the oxygen evolution reaction (OER). The OER is considered more challenging than the HER, as it uses four electrons to release O₂ and thus requires more energy to complete. Completing these reactions faster requires highly efficient and long-lived electrocatalysts (ECs). Conventionally, noble metal catalysts (Ir/Ru oxides) were used as electrocatalysts, however, their high price and scarcity are the major hurdles to advancing their water splitting applications. Further, a range of electrocatalyst materials including inexpensive and widespread transition-metal-based mono metals and binary metal alloys/oxides, metal nitrides, transition metal chalcogenides, metal phosphides, and metal-free carbon materials, have been reported extensively for use as electrocatalysts. However, for economic viability, despite all those advancements, some competent and modest electrocatalytic systems, obtainable by straightforward methods and inexpensive precursors with high electroactive sites and enhanced catalytic activity, still need to be disclosed.

### SUMMARY

In an exemplary embodiment, an electrocatalyst is described. The electrocatalyst includes a porous foam substrate; and a catalytically active layer comprising NiVOx nanostructures. The catalytically active layer is disposed on an exterior surface and an interior pore surface of the porous metal foam substrate, wherein “x” is in the range of 1 to 3.

In some embodiments, a first NiVOx nanostructures are in the form of overlapping NiVOx nanosheets.

In some embodiments, a second NiVOx nanostructures include NiVOx nanoparticles distributed on a surface of the first NiVOx nanostructure.

In some embodiments, a third NiVOx nanostructures are in a form of overlapping NiVOx nanoparticles.

In an exemplary embodiment, a method of preparing the electrocatalyst is described. The method includes heating the porous foam substrate to a deposition temperature of 250° C. to 750° C. in a reactor; and introducing, at the deposition temperature, into the reactor an aerosol including a mixture of vanadyl acetylacetonate and nickel acetylacetonate, and a solvent, thereby depositing a NiVOx layer on the porous foam substrate.

In some embodiments, the porous foam substrate is selected from a group consisting of nickel foam and titanium foam.

In some embodiments, a method for preparing the electrocatalyst further includes aerosolizing a solution or suspension of the mixture of vanadyl acetylacetonate and nickel acetylacetonate in the solvent to form the aerosol, wherein the solvent is at least one selected from the group consisting of isopropyl alcohol, ethanol, methanol, chloroform, dichloromethane, and dimethylsulfoxide prior to introducing the aerosol into the reactor.

In some embodiments, the weight ratio of the mixture of vanadyl acetylacetonate and nickel acetylacetonate to the solvent is 25:1 to 250:1.

In some embodiments, aerosolizing the solution or the suspension of the mixture is performed with an ultrasonic humidifier.

In some embodiments, introducing the aerosol into the reactor includes flowing the aerosol with an inert gas, including N₂, Ar, He, and/or Ne, from an aerosolization vessel to the reactor.

In some embodiments, the aerosol is deposited on the porous foam substrate for a deposition time of 5 to 250 minutes.

In some embodiments, the NiVOx layer on the porous foam substrate has an exchange current density of 1 to 6 mA/cm².

In some embodiments, the NiVOx layer on the porous foam substrate has a specific activity of 0.5 to 4 mA/cm².

In some embodiments, the NiVOx layer on the porous foam substrate has a mass activity of 100 to 2000 mA/mg.

In some embodiments, the NiVOx layer on the porous foam substrate has a peak current density of 100 to 1400 mA/cm².

In some embodiments, the NiVOx layer on the porous foam substrate has a charge transfer resistance of 0.75 to 4Ω.

In an exemplary embodiment, a method of using the electrocatalyst for water oxidation is described. The method includes contacting the electrocatalyst with an aqueous electrolyte solution having a pH of 8 to 14, and applying a potential of 1.30 to 1.70 V to the electrocatalyst and a counter electrode immersed in the aqueous electrolyte solution.

The foregoing general description of the illustrative present disclosure and the following detailed description thereof are merely exemplary aspects of the teachings of this disclosure and are not restrictive.

### BRIEF DESCRIPTION OF THE DRAWINGS

A more complete appreciation of this disclosure and many of the attendant advantages thereof will be readily obtained as the same becomes better understood by reference to the following detailed description when considered in connection with the accompanying drawings, wherein:

FIG. 1 is a schematic illustration for fabrication of NiVOx type catalytic films over nickel foam (NF) surface via aerosol assisted chemical vapor deposition (AACVD) method by varying deposition time from 60 to 180 minutes, according to certain embodiments;

FIG. 2A shows X-ray diffractogram (XRD) spectra of NiVOx film samples prepared for different periods of 60, 120, and 180 minutes on the NF substrate, according to certain embodiments;

FIG. 2B shows deposition of pristine components of NiO, VO, and NiVOx −180 minutes on a plain glass substrate, according to certain embodiments;

FIG. 3A shows energy dispersive X-ray spectroscopy (EDX) spectra of NiVOx film samples prepared on plain glass substrates with measured Ni/V atomic concentrations (%) from a corresponding film surface of NiVOx type electrocatalysts prepared for continuous 60 minutes, according to certain embodiments;

FIG. 3B shows energy dispersive X-ray spectroscopy (EDX) spectra of NiVOx film samples prepared on the plain glass substrates with measured Ni/V atomic concentrations (%) from a corresponding film surface of NiVOx type electrocatalysts prepared for continuous 120 minutes, according to certain embodiments;

FIG. 3C shows energy dispersive X-ray spectroscopy (EDX) spectra of NiVOx film samples prepared on the plain glass substrates with measured Ni/V atomic concentrations (%) from a corresponding film surface of NiVOx type electrocatalysts prepared for continuous 180 minutes, according to certain embodiments;

FIG. 4A shows electrocatalytic investigations-consecutive first 50 polarization curves for NiVOx/NF₆₀ showing in-situ electrochemical activation of a catalyst recorded at the scan rate of 10 mV/s in 1.0 M aq. KOH electrolyte solution, according to certain embodiments;

FIG. 4B shows an enlarged view of FIG. 3A, according to certain embodiments;

FIG. 5A shows electrocatalytic investigations—concurrent 1^{st}, 50^{th}, and 60^{th} forward potential sweeps for NiVOx/NF60 showing in-situ electrochemical activation of the catalyst recorded at the scan rate of 10 mV/s in 1.0 M aq. KOH electrolyte solution, according to certain embodiments;

FIG. 5B is an enlarged view of FIG. 5A, according to certain embodiments;

FIG. 6A whose electrocatalytic investigations—consecutive first 80 polarization curves for NiVOx/NF120 showing in-situ electrochemical activation of the catalyst recorded at the scan rate of 10 mV/s in 1.0 M aq. KOH electrolyte solution, according to certain embodiments;

FIG. 6B shows an enlarged view of FIG. 6A, according to certain embodiments;

FIG. 7A electrocatalytic investigations; a) concurrent 1^{st}, 80^{th}, and 100^{th} forward potential sweeps for NiVOx/NF₁₂₀ showing in-situ electrochemical activation of the catalyst recorded at the scan rate of 10 mV/s in 1.0 M aq. KOH electrolyte solution, according to certain embodiments;

FIG. 7B shows an enlarged view of FIG. 7A, according to certain embodiments;

FIG. 8A shows electrocatalytic investigations—consecutive first 100 polarization curves for NiVOx/NF₁₈₀ showing in-situ electrochemical activation of the catalyst recorded at the scan rate of 10 mV/s in 1.0 M aq. KOH electrolyte solution, according to certain embodiments;

FIG. 8B shows an enlarged view of FIG. 8A, according to certain embodiments;

FIG. 9A shows electrocatalytic investigations-concurrent 1^{st} to 40^{th}, 41^{st}, 80^{th}, and 100^{th} forward potential sweeps for NiVOx/NF180 showing in-situ electrochemical activation of catalyst recorded at the scan rate of 10 mV/s in 1.0 M aq. KOH electrolyte solution, according to certain embodiments;

FIGS. 9B-9C shows enlarged views of FIG. 9A, according to certain embodiments;

FIG. 10A shows electrocatalytic investigations-concurrent 1^{st}, 41^{st}, 60^{th}, 80^{th}, and 100^{th} forward potential sweeps for NiVOx/NF₁₈₀ showing in-situ electrochemical activation of catalyst recorded at the scan rate of 10 mV/s in 1.0 M aq. KOH electrolyte solution, according to certain embodiments;

FIG. 10B shows an enlarged view of FIG. 10A, according to certain embodiments;

FIG. 11 shows electrocatalytic investigations-an enlarged view of polarization curves for NiVOx/NF₆₀, NiVOx/NF₁₂₀, and NiVOx/NF₁₈₀ recorded at the scan rate of 2 mV/s in 1.0 M aq. KOH electrolyte solution, according to certain embodiments;

FIG. 12A shows electrocatalytic investigations-concurrent forward potential sweeps for VOx-NF₁₈₀, according to certain embodiments;

FIG. 12B shows enlarged view of FIG. 12A, according to certain embodiments;

FIG. 12C shows NiOx-NF₁₈₀, according to certain embodiments;

FIG. 12D shows enlarged view of FIG. 12C showing in-situ electrochemical activation of the catalysts recorded at the scan rate of 10 mV/s in 1.0 Maq. KOH electrolyte solution, according to certain embodiments;

FIG. 13A shows electrocatalytic investigations-polarization curves for NiVOx/NF₁₈₀, NiOx/NF, VOx/NF, and bare NF substrate recorded at the scan rate of 2 mV/s in 1.0 M aq. KOH electrolyte solution, according to certain embodiments;

FIG. 13B shows an enlarged view of polarization curves, according to certain embodiments;

FIG. 14 shows a comparison of X-ray photon spectroscopy (XPS) spectra of pristine NiOx and bimetallic NiVOx samples, according to certain embodiments;

FIG. 15 shows a high-resolution Ni 2p XPS spectrum of the pristine NiOx sample, according to certain embodiments;

FIG. 16A shows electrocatalytic investigations-polarization curves for NiVOx/NF₆₀, NiVOx/NF₁₂₀, NiVOx/NF₁₈₀, NiVOx/NF₂₄₀, and bare NF substrate recorded at the scan rate of 2mV/s in 1.0 M aq. KOH electrolyte solution, according to certain embodiments;

FIG. 16B shows an enlarged view of polarization curves (FIG. 16A), according to certain embodiments;

FIG. 17 shows Nyquist plots recorded at 1.58 V vs. RHE for NiVOx/NF₁₈₀ and NiVOx/NF₂₄₀ (inset showing simplified Randles circuit diagram), according to certain embodiments;

FIG. 18 shows electrocatalytic investigations; enlarged view of polarization curves for NiVOx/NF₁₈₀ before and after extended period water electrolysis experiments recorded at the scan rate of 2 mV/s in 1.0 M aq. KOH electrolyte solution, according to certain embodiment scans;

FIG. 19 shows a time vs. potential curve for NiVOx/NF₁₈₀ at a fixed current density of 500 mA/cm² in 1.0 M aq. KOH electrolyte solution, according to certain embodiments;

FIG. 20A shows an overview scanning electron microscope (SEM) image of the NiVOx/NF₁₈₀ sample after a long-term OER stability test, according to certain embodiments;

FIG. 20B shows a high-resolution SEM image of the NiVOx/NF₁₈₀ sample after a long-term OER stability test, according to certain embodiments;

FIG. 21 shows energy-dispersive X-ray spectroscopy (EDX) spectra of NiVOx/NF₁₈₀ sample after a long-term OER study, according to certain embodiments;

FIG. 22A shows a high-resolution V 2p XPS spectrum of the NiVOx/NF₁₈₀ sample after a long-term OER stability test, according to certain embodiments;

FIG. 22B shows a high-resolution Ni 2p XPS spectrum of the NiVOx/NF₁₈₀ sample after a long-term OER stability test, according to certain embodiments; and

FIG. 22C shows a high-resolution O1s XPS spectrum of the NiVOx/NF₁₈₀ sample after a long-term OER stability test, according to certain embodiments.

### DETAILED DESCRIPTION

The present disclosure will be better understood with reference to the following definitions.

It will be understood that the terms “comprises” and/or “comprising,” when used in this specification, specify the presence of stated features, steps, operations, elements, and/or components, but do not preclude the presence or addition of one or more other features, steps, operations, elements, components, and/or groups thereof.

In the drawings, like reference numerals designate identical or corresponding parts throughout the several views. Further, as used herein, the words “a,” “an” and the like generally carry a meaning of “one or more,” unless stated otherwise. Also, the use of “or” means “and/or” unless stated otherwise. Similarly, “comprise,” “comprises,” “comprising” “include,” “includes,” and “including” are interchangeable and not intended to be limiting.

Furthermore, the terms “approximately,” “approximate,” “about,” and similar terms generally refer to ranges that include the identified value within a margin of 20%, 10%, or preferably 5%, and any values there between. For example, if a stated value is about 8.0, the value may vary in the range of 8±1.6, ±1.0, ±0.8, ±0.5, ±0.4, ±0.3, ±0.2, or ±0.1.

Disclosure of values and ranges of values for specific parameters (such as temperatures, molecular weights, weight percentages, etc.) are not exclusive of other values and ranges of values useful herein. It is envisioned that two or more specific exemplified values for a given parameter may define endpoints for a range of values that may be claimed for the parameter. For example, if Parameter X is exemplified herein to have value A and also exemplified to have value Z, it is envisioned that parameter X may have a range of values from about A to about Z. Similarly, it is envisioned that disclosure of two or more ranges of values for a parameter (whether such ranges are nested, overlapping or distinct) subsume all possible combination of ranges for the value that might be claimed using endpoints of the disclosed ranges. For example, if parameter X is exemplified herein to have values in the range of 1-10 it also describes subranges for Parameter X including 1-9, 1-8, 1-7, 2-9, 2-8, 2-7, 3-9, 3-8, 3-7, 2-8, 3-7, 4-6, or 7-10, 8-10 or 9-10 as mere examples. A range encompasses its endpoints as well as values inside of an endpoint, for example, the range 0-5 includes 0, >0, 1, 2, 3, 4, <5 and 5.

As used herein, the words “preferred” and “preferably” refer to embodiments of the technology that afford certain benefits, under certain circumstances. However, other embodiments may also be preferred, under the same or other circumstances. Furthermore, the recitation of one or more preferred embodiments does not imply that other embodiments are not useful, and is not intended to exclude other embodiments from the scope of the technology.

As referred to herein, all compositional percentages are by weight of the total composition, unless otherwise specified. As used herein, the word “include,” and its variants, is intended to be non-limiting, such that recitation of items in a list is not to the exclusion of other like items that may also be useful in the materials, compositions, devices, and methods of this technology.

The present disclosure further includes all isotopes of atoms occurring in the present compounds. Isotopes include those atoms having the same atomic number but different mass numbers. By way of general example, and without limitation, isotopes of hydrogen include deuterium and tritium, isotopes of oxygen include ¹⁶O, ¹⁷O and ¹⁸O. Isotopically labeled compounds of the disclosure can generally be prepared by conventional techniques known to those skilled in the art or by processes and methods analogous to those described herein, using an appropriate isotopically labeled reagent in place of the non-labeled reagent otherwise employed.

As defined here, an aerosol is a suspension of solid or liquid particles in a gas. An aerosol includes both the particles and the suspending gas. Primary aerosols contain particles introduced directly into the gas, while secondary aerosols form through gas-to-particle conversion. There are several measures of aerosol concentration. Environmental science and health fields often use the mass concentration (M), defined as the mass of particulate matter per unit volume with units such as μg/m³. Also commonly used is the number concentration (N), the number of particles per unit volume with units such as number/m³ or number/cm³. The size of particles has a major influence on their properties, and the aerosol particle radius or diameter (d_{P}) is a key property used to characterize aerosols. Aerosols vary in their dispersity. A monodisperse aerosol, producible in the laboratory, contains particles of uniform size. Most aerosols, however, as polydisperse colloidal systems, exhibit a range of particle sizes. Liquid droplets are almost always nearly spherical, but scientists use an equivalent diameter to characterize the properties of various shapes of solid particles, some very irregular. The equivalent diameter is the diameter of a spherical particle with the same value of some physical property as the irregular particle. The equivalent volume diameter (dₑ) is defined as the diameter of a sphere of the same volume as that of the irregular particle. Also commonly used is the aerodynamic diameter. The aerodynamic diameter of an irregular particle is defined as the diameter of the spherical particle with a density of 1000 kg/m³ and the same settling velocity as the irregular particle.

The present disclosure relates to a method of producing electrocatalysts. This method involves contacting an aerosol with a substrate to deposit a nanostructured layer onto the substrate, thereby forming the electrocatalyst. As described here, “contacting an aerosol with a substrate” is considered to be synonymous with “contacting a substrate with an aerosol.” Both phrases mean that the substrate is exposed to the aerosol, so that a portion of the suspended particles of the aerosol directly contact the substrate. Contacting may also be considered equivalent to “introducing” or “depositing,” such as “depositing an aerosol onto a substrate.” In one embodiment, the contacting may be considered aerosol-assisted chemical vapor deposition (AACVD). In one embodiment, the method of making the electrocatalyst may be considered a one-step method, as the formation of the nanostructured layer takes place immediately following and/or during the contacting of the aerosol with the substrate.

Aspects of this invention provide a method of making an electrocatalyst, comprising aerosol-assisted chemical vapor depositing a mixture comprising nickel and vanadium precursors on a substrate to form nanostructures on the substrate. The aerosol contains a carrier gas, a mixture comprising nickel and vanadium precursors, and a solvent. In one embodiment, the aerosol consists of, or consists essentially of, a carrier gas, a mixture comprising nickel and vanadium precursors, and a solvent before the contacting, preferably immediately before the contacting. Preferably, the mixture comprising nickel and vanadium precursors is dissolved or dispersed in the solvent. In one embodiment, the mixture comprising nickel and vanadium precursors has an acetylacetone or acetylacetonate (acac) ligand, a trifluoro-acetate (TFA) ligand, an acetate ligand (OAc), an isopropanol (iPrOH) ligand, a tetrahydrofuran (THF) ligand, and/or a water (H₂O) ligand. In one embodiment, the substrate is a metal substrate or porous foam. The precursors may include molybdenum and cobalt in addition to the Ni and V. A metal substrate is at least one selected from the group consisting of tin, aluminum, zinc, and nickel foam. The porous foam substrate may be nickel foam or titanium foam. In an embodiment, the substrate is nickel foam.

Exemplary solvents applicable to the method disclosed herein include, but are not limited to toluene, tetrahydrofuran, acetic acid, acetone, acetonitrile, butanol, dichloromethane, chloroform, chlorobenzene, dichloroethane, diethylene glycol, diethyl ether, dimethoxyethane, dimethylformamide, dimethyl sulfoxide, ethanol, ethyl acetate, ethylene glycol, heptane, hexamethylphosphoramide, hexamethylphosphorous triamide, methanol, methyl t-butyl ether, methylene chloride, pentane, cyclopentane, hexane, cyclohexane, benzene, dioxane, propanol, isopropyl alcohol, pyridine, triethyl amine, propandiol-1,2-carbonate, ethylene carbonate, propylene carbonate, nitrobenzene, formamide, γ-butyrolactone, benzyl alcohol, n-methyl-2-pyrrolidone, acetophenone, benzonitrile, valeronitrile, 3-methoxy propionitrile, dimethyl sulfate, aniline, n-methylformamide, phenol, 1,2-dichlorobenzene, tri-n-butyl phosphate, ethylene sulfate, benzenethiol, dimethyl acetamide, N,N-dimethylethaneamide, 3-methoxypropionnitrile, diglyme, cyclohexanol, bromobenzene, cyclohexanone, anisole, diethylformamide, 1-hexanethiol, ethyl chloroacetate, 1-dodecanthiol, di-n-butylether, dibutyl ether, acetic anhydride, m-xylene, o-xylene, p-xylene, morpholine, diisopropyletheramine, diethyl carbonate, 1-pentandiol, n-butyl acetate, and 1-hexadecanthiol. In one embodiment, the solvent comprises pyridine, N,N-dimethylformamide (DMF), N,N-dimethylacetamide, N-methyl pyrrolidone (NMP), hexamethylphosphoramide (HMPA), dimethyl sulfoxide (DMSO), acetonitrile, tetrahydrofuran (THF), 1,4-dioxane, dichloromethane, chloroform, carbon tetrachloride, dichloroethane, acetone, ethyl acetate, pentane, hexane, decalin, dioxane, benzene, toluene, xylene, o-dichlorobenzene, diethyl ether, methyl t-butyl ether, methanol, ethanol, ethylene glycol, isopropanol, propanol, n-butanol, and mixtures thereof. In a preferred embodiment, the solvent is acetone, methanol, ethanol, and/or isopropanol. More preferably the solvent is methanol. In one embodiment, the solvent may comprise water. The water used as a solvent or for other purposes may be tap water, distilled water, bidistilled water, deionized water, deionized distilled water, reverse osmosis water, and/or some other water. In one embodiment, the water is bidistilled or treated with reverse osmosis to eliminate trace metals. Preferably the water is bidistilled, deionized, deionized distilled, or reverse osmosis water, and at 25° C. has a conductivity of less than 10 μS·cm⁻¹, preferably less than 1 μS·cm⁻¹; a resistivity of greater than 0.1 MΩ·cm, preferably greater than 1 MΩ·cm, more preferably greater than 10 MΩ·cm; a total solid concentration of less than 5 mg/kg, preferably less than 1 mg/kg; and a total organic carbon concentration of less than 1000 μg/L, preferably less than 200 μg/L, more preferably less than 50 μg/L.

In some embodiments, the method includes aerosol being introduced into the reactor using a carrier gas. In some embodiments, the carrier gas is an inert gas. In an embodiment, the inert gas may include one or more selected from N₂, Ar, He, and/or Ne. Preferably the carrier gas is N₂. Preferably the solvent and the mixture comprising nickel and vanadium are able to form an appropriately soluble solution that can be dispersed in the carrier gas as aerosol particles. For instance, the mixture comprising nickel and vanadium may first be dissolved in a volume of solvent, and then pumped through a jet nozzle in order to create an aerosol mist. In other embodiments, the mist may be generated by a piezoelectric ultrasonic generator. Other nebulizers and nebulizer arrangements may also be used, such as concentric nebulizers, cross-flow nebulizers, entrained nebulizers, V-groove nebulizers, parallel path nebulizers, enhanced parallel path nebulizers, flow blurring nebulizers, and piezoelectric vibrating mesh nebulizers.

In one embodiment, the aerosol has a mass concentration M, of 10 μg/m³-1,000 mg/m³, preferably 50 μg/m³-1,000 μg/m³. In one embodiment, the aerosol has a number concentration N, in a range of 10³-10⁶, preferably 10⁴-10⁵ cm⁻³. In other embodiments, the aerosol may have a number concentration of less than 10³ or greater than 10⁶. The aerosol particles or droplets may have an equivalent volume diameter (dₑ) in a range of 20 nm-100 μm, preferably 0.5-70 μm, more preferably 1-50 μm, though in some embodiments, aerosol particles or droplets may have an average diameter of smaller than 0.2 μm or larger than 100 μm.

In one embodiment, during the contacting of the aerosol, the carrier gas has a flow rate in a range of 20-250 cm³/min, preferably 50-230 cm³/min, more preferably 75-200 cm³/min, even more preferably 100-150 cm³/min, or about 120 cm³/min. Preferably, the aerosol has a flow rate similar to the carrier gas, with the exception of the portion of aerosol that gets deposited on the substrate. In one embodiment, the aerosol may enter the chamber and the flow rate may be stopped, so that a portion of aerosol may settle on the substrate.

The contacting and/or introducing may take place within a closed chamber or reactor, and the aerosol may be generated by dispersing a solution of the mixture comprising nickel and vanadium and solvent. In one embodiment, the mixture comprises vanadyl acetylacetonate, nickel acetylacetonate, and methanol. The mixture, including vanadyl acetylacetonate and nickel acetylacetonate, is introduced into a reactor at a vanadyl acetylacetonate: nickel acetylacetonate molar ratio of about 1:10 to 10:1, preferably 1:5 to 5:1, preferably 1:3 to 3:1, preferably 1:2 to 2:1, preferably 1:1. In one embodiment, a weight ratio of vanadyl acetylacetonate and nickel acetylacetonate to the solvent in the mixture is 25:1 to 250:1. In one embodiment, this dispersing may be increased by fans, jets, or pumps. However, in another embodiment, an aerosol may be formed in a closed chamber with a substrate where the aerosol particles are allowed to diffuse towards or settle on the substrate. In some embodiments, the aerosol/droplets are formed with the help of an ultrasonic humidifier. In one embodiment, the closed chamber or reactor may have a length of 10-100 cm, preferably 12-30 cm, and a diameter or width of 1-10 cm, preferably 2-5 cm. In other embodiments, the closed chamber or reactor may have an interior volume of 0.2-100 L, preferably 0.3-25 L, more preferably 0.5-10 L. In one embodiment, the closed chamber or reactor may comprise a cylindrical glass vessel, such as a glass tube.

Being in a closed chamber, the interior pressure of the chamber (and thus the pressure of the aerosol) may be controlled. The pressure may be practically unlimited, but need not be an underpressure or an overpressure. Preferably the chamber and substrate are heated and held at a temperature prior to the contacting, so that the temperature may stabilize. The chamber and substrate may be heated for a time period of 5 min-1 hour, preferably 10-20 min prior to the contacting.

Furthermore, the aerosol-assisted chemical vapor depositing is carried out for from 1 to 600 min, preferably 20 to 550 min, preferably 20 to 450 min, preferably 30 to 400 min, preferably 30 to 350 min, preferably 30 to 250 min at a fixed temperature of 200-1000° C., preferably 300-900°° C., preferably 400-800° C., preferably 400-700° C. The deposition time is one of the most critical features affecting the performance of the electrocatalyst. In yet other embodiments of this invention, the aerosol-assisted chemical vapor depositing is carried out for from 30, 40, 50, 60, 70, 80, 90, 100, 110, 120, 130, 140, 150, 160, 170, 180, and/or 190 to 200 min at a fixed temperature of 400, 430, 460, 490, 510, 540, 570, 600, 630, and/or 660 to 700° C.

The method of making electrocatalyst may further comprise a step of cooling the electrocatalyst after the contacting. The electrocatalyst may be cooled to a temperature between 10 to 45° C., 20 to 40° C., or 25 to 35° C. under an inert gas (such as N₂ or Ar) over a time period of 0.5-5 h, 0.75-4 h, 1-3 h, 1.25-2.5 h, or 1.5-2 h. In one embodiment, the electrocatalyst may be left in the chamber and allowed to cool.

In an embodiment, the thickness of the NF substrate is in the range of 0.5-20 mm, preferably 1-15 mm, preferably 1-10 mm, preferably 1-5 mm, preferably 1-3 mm. The substrate may be of any desirable shape, such as, a circle, a triangle, a rectangle, a pentagon, a hexagon, an irregular polygon, a circle, an oval, an ellipse, or a multilobe. Preferably, the substrate is rectangular in shape with a length and width of 0.5-5 cm, 1-4 cm, or 2-3 cm, respectively. The substrate may have an area in a range of 0.25-25 cm², preferably 0.5-5 cm², more preferably about 2 cm².

The electrocatalyst further includes a catalytically active layer including NiVOx nanostructures, where “x” is 1 to 3, preferably 2 to 3. In a preferred embodiment, “x”=3. The catalytically active layer is disposed on an exterior surface and an interior pore surface of the porous foam substrate.

In an embodiment, first NiVOx nanostructures having a vanadyl acetylacetonate: nickel acetylacetonate molar ratio of about 1:10 to 10:1, preferably 1:5 to 5:1, preferably 1:3 to 3:1, preferably 1:2 to 2:1, preferably 1:1 are in the form of overlapping NiVOx nanosheets having an average thickness in a range of 0.01-50 μm, preferably 0.5-10 μm, more preferably 0.5-3 μm, even more preferably 0.5-2 μm, or about 500-700 nm, and an average length in a range of 0.01-100 μm, preferably 0.5-50 μm or 1-10 μm.

In an embodiment, second NiVOx nanostructures having a vanadyl acetylacetonate: nickel acetylacetonate molar ratio of about 1:10 to 10:1, preferably 1:5 to 5:1, preferably 1:3 to 3:1, preferably 1:2 to 2:1, preferably 1:1 include NiVOx nanoparticles having an average diameter of from 300-1000 nm, preferably 400-800 nm or 500-700 nm with 300-1000 nm, preferably 400-800 nm or 500-700 nm distance between nanoparticles and an average thickness in a range of 0.01-50 μm, preferably 0.5-10 μm, more preferably 0.8-3 μm, even more preferably 0.9-2 μm, or about 1 μm distributed on a surface of the first NiVOx nanostructures.

In an embodiment, third NiVOx nanostructures having a vanadyl acetylacetonate: nickel acetylacetonate molar ratio of about 1:10 to 10:1, preferably 1:5 to 5:1, preferably 1:3 to 3:1, preferably 1:2 to 2:1, preferably 1:1 are in a form of overlapping NiVOx nanoparticles having an average thickness in a range of a range of 0.01-100 um, preferably 0.5-50 μm, more preferably 0.5-10 μm, even more preferably 0.5-2 μm, or about 500-700 nm. In other words, the second NiVOx nanostructures may be sandwiched between the first NiVOx nanostructures and the third NiVOx nanostructures. The deposition of the catalytically active layer on the NF substrate is preferably achieved via an AACVD technique.

In one embodiment, the thickness of the nanostructures may vary from location to location on the substrate by 1-30%, 5-20%, or 8-10% relative to the average thickness of the nanostructures deposited on the substrate. In a preferred embodiment, 70-100%, more preferably 80-99%, even more preferably 85-97% of the surface of the substrate is covered with the nanostructures, though in some embodiments, less than 70% of the surface of the substrate is covered with the nanostructures.

In an embodiment, the method includes aerosolizing a solution or suspension of the mixture of vanadyl acetylacetonate and nickel acetylacetonate in the solvent to form the aerosol before introducing the mixture into the reactor while exposing the mixture to an ultrasonic humidifier. In one embodiment, the electrocatalyst has an exchange current density of 0.3 to 10 mA/cm², preferably 0.4 to 8 mA/cm², preferably 0.5 to 6 mA/cm², preferably 1 to 6 mA/cm².

In one embodiment, the electrocatalyst has a specific activity of 0.3 to 10 mA/cm², preferably 0.4 to 8 mA/cm², preferably 0.5 to 6 mA/cm², preferably 0.5 to 4 mA/cm².

In one embodiment, the electrocatalyst has a mass activity of 50 to 2500 mA/mg, preferably 100 to 2300 mA/mg, preferably 100 to 2200 mA/mg, preferably 100 to 2100 mA/mg, preferably 100 to 2000 mA/mg.

In one embodiment, the electrocatalyst has a peak current density of 50 to 2000 mA/cm², preferably 50 to 1800 mA/cm², preferably 100 to 1700 mA/cm², preferably 100 to 1500 mA/cm², preferably 100 to 1400 mA/cm².

In one embodiment, the electrocatalyst has a charge transfer resistance of 0.5 to 10Ω, preferably 0.6 to 8Ω, preferably 0.7 to 6Ω, preferably 0.73 to 5Ω, preferably 0.75 to 4Ω.

The electrocatalyst of the present disclosure may be used in water-splitting reactions. In some embodiments, the electrocatalyst may also be used in the field of batteries, fuel cells, photochemical cells, water splitting cells, electronics, water purification, hydrogen sensors, semiconductors (such as field-effect transistors), magnetic semiconductors, capacitors, data storage devices, biosensors (such as redox protein sensors), photovoltaics, liquid crystal screens, plasma screens, touch screens, OLEDs, antistatic deposits, optical coatings, reflective coverings, anti-reflection coatings, and/or reaction catalysis.

A method of using an electrocatalyst for water oxidation is described. The method includes contacting the electrocatalyst with an aqueous electrolyte solution having a pH of 8 to 14, and further applying a potential of 1.10 to 2 V, preferably 1.20 to 1.9 V, preferably 1.25 to 1.8 V, preferably 1.30 to 1.70 V to the electrocatalyst and a counter electrode immersed in the aqueous electrolyte solution. The electrocatalyst forms the working electrode, while the counter electrode forms the auxiliary electrode. The outer surface of the counter electrode includes an inert, electrically conducting chemical substance, such as platinum, gold, or carbon. In one embodiment, the counter electrode may be a wire, a rod, a cylinder, a tube, a scroll, a sheet, a piece of foil, a woven mesh, a perforated sheet, or a brush. The counter electrode material should thus be sufficiently inert to withstand the chemical conditions in the electrolyte solution, such as acidic or basic pH values, without substantially degrading during the electrochemical reaction. The counter electrode preferably should not leach out any chemical substance that interferes with the electrochemical reaction or might lead to undesirable contamination of either electrode. The electrolyte solution includes water and an inorganic base at a concentration of 0.05-2.0 M, preferably 0.1-1.8 M, preferably 0.1-1.6 M, preferably 0.1-1.4 M, preferably 0.1-1.2 M, preferably 0.1-1.0 M. In one embodiment, the electrolyte solution includes water and an inorganic base at a concentration of 0.1-1.0 M. In an embodiment, the inorganic base is preferably KOH.

### EXAMPLES

The following examples describe and demonstrate exemplary embodiments of the fabrication of NiVOx electrocatalysts over the NF substrate for high-performance OER. The examples are provided solely for illustration and are not to be construed as limitations of the present disclosure, as many variations thereof are possible without departing from the spirit and scope of the present disclosure.

Materials and Methods

All of the chemicals and reagents were of analytical grade, obtained from Sigma-Aldrich, and used without further purification. Nickel (II) acetylacetonate (Ni(C₅H₇O₂)₂ (99.999%), vanadium (IV)-oxy acetylacetonate VO(C₅H₇O₂)₂) (99.999%), and solvent (methanol) used in this work were purchased from Sigma-Aldrich. Methanol was used after the double-distillation process. Nickel foam (NF) with a thickness of 0.9 mm and porosity of 93% was obtained from Goodfellow global suppliers for materials. Commercially available RuO₂ NPs were purchased from Aldrich and used as received without any purification step. The solutions were prepared using highly purified water from a Millipore-Milli-Q system (18.2 MΩcm at 25° C.). All of the analyses were carried out at room temperature.

### Preparation of a Working Electrode

The nickel foam substrate was decorated with electrocatalytically active mixed-metal nickel vanadium oxide (NiVOₓ) films by adopting an aerosol-assisted chemical vapor deposition (AACVD) strategy. The precursors VO(acac)₃ (100 mg, 0.4 mmol) and Ni(acac)₂ (100 mg, 0.4 mmol) were simultaneously dissolved in 20 mL of methanol without using any solubilizing agent. After 10 min of stirring, the resulting sea-green solution was directly employed as a precursor feedstock for thin-film deposition. The deposition time was systematically varied from 60 to 120 and 180 minutes by keeping the deposition temperature fixed at 480°° C. The as-synthesized film samples were NiVOx/NF₆₀, NiVOx/NF₁₂₀, and NiVOx/NF₁₈₀. Briefly, in the AACVD experiment, the liquefied precursor is converted into a gaseous stream with the help of an ultrasonic humidifier. The precursor cloud is transported toward a horizontal tube furnace with the help of nitrogen (N₂, 99.9% purity) as a carrier gas at a flow rate of 120 mL/min. The NF substrate is placed inside the reactor tube of the tube furnace. The temperature of the tube furnace is set at 480°° C. The precursor gaseous stream directly interacts with the pre-heated surface of NF and undergoes surface reactions to deposit thin films. This procedure is repeated for the desired period of 60, 120, and 180 minutes. Once the deposition experiment is over, the precursor stream is stopped, and the tube furnace is switched off. However, the N₂ gas supply remains on until the tube furnace is cooled down to room temperature. The NF substrates are uniformly and firmly coated with the desired product of NiVOx.

### Analytical Measurement

X-ray Diffraction pattern analysis: A MiniFlex benchtop X-ray diffractometer (XRD, Rigaku, Japan) used Cu Kα1 radiation (α=0.15416 nm) to record the XRD patterns.

Scanning Electron Microscopy (SEM): The surface patterns were investigated using a scanning electron microscope (JEOL SEM model JSM-6460).

EDX Analysis: Energy-dispersive X-ray spectrophotometry (model INCA Energy 200, Oxford Instruments) was performed for compositional studies of the films.

Transmission Electron Microscopy (TEM): A field emission transmission electron microscope (FETEM) (JEOL-JEM2100F, Japan) operated at an accelerating voltage of 200 kV was employed to examine the thin-film microstructure.

X-ray Photoelectron Spectroscopy (XPS): The oxidation and chemical states of the elements were investigated with the X-ray photoelectron spectroscopy (XPS) technique (Thermo Fisher Scientific, model: ESCALAB 250Xi).

Electrochemical Investigations: All electrochemical OER measurements were carried out using a Gamry Interface 1010 E computer-controlled Potentiostat. Experiments were performed using a typical three-electrode glass cell with NiVOx/NF (exposed surface area=1 cm²) as a working electrode. A spiral-shaped platinum wire was used as a counter electrode, and saturated silver/silver chloride (sat. Ag/AgCl) and saturated mercury/mercury oxide [(Hg/HgO) 0.1 M NaOH] as reference electrodes. Electrochemical experiments such as cyclic voltammetry (CV), linear sweep voltammetry (LSV), chronoamperometry (CA), or controlled potential electrolysis (CPE) and chronopotentiometry (CP) or controlled current electrolysis (CCE) were performed in a 1.0 M aq. KOH electrolyte solution with a pH of 14. Chronopotentiometry measurements were carried out for the long-term durability test at two different current density values over several hours. Electrochemical impedance spectroscopy (EIS) measurements were commenced to study solution resistance and charge-transfer resistance at the electrode/electrocatalyst-electrolyte interface. Nyquist plots were collected at a potential of 1.58 V vs. RHE at 100,000 to 0.1 Hz. The potential reported in all our experiments was converted to the reversible hydrogen electrode (RHE) according to the Nernst equation (eq S1). The conversion of all the measured potentials to the reversible hydrogen electrode (RHE) was done by the Nernst equation (Equation. 1).

$$ERGE = EAg / AgCl + ( 0.1976 + 0.059 * pH ) V \qquad ( Equation . 1 )$$

The overpotential calculation of NiVOx/NF electrocatalyst for OER was performed utilizing equation (Equation. 2).

$$η = ERHE - 1.23 V \qquad ( Equation . 2 )$$

where η accounts for overpotential

All data are presented with 10% IR corrections (unless otherwise mentioned). Considering the solution resistance, IR corrections were made using eq S3. Contact resistance (Rs) was derived from impedance measurements for ohmic drop correction. 10% IR corrections were conducted for all electrochemical data such as cyclic voltammetry, controlled-current electrolysis, controlled potential electrolysis, and Tafel plot calculations) using the following equation (Equation. 3).

$${E}_{actual} - I R = {E}_{corrected} \qquad ( Equation . 3 )$$

where Eactual is potential vs. Ag/AgCl or SCE

The Tafel slope was calculated from the linear region of the polarization curve near the potential region where the oxygen evolution reaction initiates (Equation. 4).

$$η = b Log j + a \qquad ( Equation . 4 )$$

where b is the Tafel slope, and a is constant

Electrochemically active surface area for each system is obtained from measuring double layer charging capacitance of electrocatalytic surface determined from the non-faradaic region of cyclic voltammetry at multiple scan rates from 10 mV/s to 60 mV/s of cyclic voltammograms. It is assumed that non-faradaic current is due to double-layer charging capacitance (C_{dl}) that yields a straight-line equation where slope presents double layer charging capacitance according to the following equation (Equation. 5).

$${i}_{c} = υ {C}_{dl} \qquad ( Equation . 5 )$$

where i_{c} is double layer charging current, ν, C_{dl} is scan rate and double-layer charging capacitance

Electrochemically active surface area is obtained by dividing double-layer capacitance with a specific capacitance of the metal electrode according to the following equation (Equation. 6).

$$ECSA = {C}_{dl} / {C}_{s} \qquad ( Equation . 6 )$$

where Cs for different metal electrodes in alkaline electrolyte solutions such as NaOH and KOH lies in the range of 0.022 to 1.30 mF/cm² as mentioned in the literature. 0.04 is chosen as the optimum value of specific capacitance for measuring the ECSA of NiVOx-based electrodes working under alkaline conditions.

To assess electrocatalytic activity, electrochemical parameters such as mass activity (MA), exchange current density (j_{exc}), intrinsic catalytic activity (jₛ), and turnover frequency (TOF) were calculated by the following standard equations (Equation. 7).

$$M A = J / Active mass of catalyst . \qquad ( Equation . 7 )$$

where, J is the current density in mA cm⁻² at a specific potential value of 1.58 V vs. RHE for comparing the electrocatalytic activities of all the thin film electrocatalysts

$$N i V {O}_{x} / {NF}_{60} = 55 mA / 0.08 mg = 687.5 mA / mg$$

$$NiVOx / {NF}_{120} = 90 mA / 0.2 mg = 450 mA / mg$$

$$NiVOx / NF 180 = 480 mA / 0.32 mg = 1500 mA / mg$$

Exchange current density J_{exc} (mA/cm²): Exchange current density is calculated considering charge transfer resistance at electrode-electrolyte interphase using the standard equation (Equation 8)

$${J}_{e x c} = RT / n A F θ \qquad ( Equation 8 )$$

where R is the universal gas constant 8.314 J (kg·m²·s⁻²)/K·mol, T is temperature 298 K, n represents the number of electrons which is 4 for oxygen evolution reaction, F is Faraday constant 96485 C (A.s)/mol, θ is charge transfer resistance Ω (kg·m²·s⁻³·A⁻²), A is the geometrical area of working electrodes that is 1 cm²

$$N i VOx / {NF}_{180} = 8.3 \; 14 J / K . mol \times 298 K / 4 \times 96485 C / mol \times 1.8 Ω \times 1 {cm}^{2} = 3.56 mA / {cm}^{2}$$

Specific activity (mA/cm²): Specific activity is calculated by the following equation (Equation. 9).

$$Specific activity ( {J}_{s} ) = I / ECSA . \qquad ( Equation . 9 )$$

where I is the current obtained from the polarization curve at a specific potential (here, we have calculated the specific activity of catalytic systems at 1.58 V vs. RHE), and ECSA is the electrochemically active surface area of the electrode

$$N i VOx / {NF}_{180} = 480 mA / 445 {cm}^{2} = 1.07 mA / {cm}^{2}$$

Determination of Turnover frequency (TOF): The turnover frequency (TOF) of NiVOx/NF₁₈₀ electrocatalyst is calculated from polarization curves. TOF is calculated at various applied potential values directly observed from polarization curves. Turnover frequency is calculated at various potential values considering the following equation (Equation. 10)

$$TOF = j \times A / 4 \times n \times F ; \qquad ( Equation . 10 )$$

where I=is the current density achieved at a specific potential value observed from the linear polarization curve (A), A=is the geometrical area of the working electrode that is 1 cm², n=is the number of moles of catalyst deposited over the substrate, 4=is the number of electron transfer during the reaction, and F=is faradaic constant (96485.3 C/mol)

$$TOF @ 1.45 V = [ ( 0.01 A ) \times ( 1 {cm}^{2} ) ] / [ ( 4 ) \times ( 2.55 \times 1 {0}^{- 6} mol ) \times ( 96485 C {mol}^{- 1} ) ] = 0.0 \; 10 {s}^{- 1}$$

$$TOF @ 1.47 V = [ ( 0.02 A ) \times ( 1 {cm}^{2} ) ] / [ ( 4 ) \times ( 2.55 \times 1 {0}^{- 6} mol ) \times ( 96485 C {mol}^{- 1} ) ] = 0.02 {s}^{- 1}$$

$$TOF @ 1.49 V = [ ( 0.04 A ) \times ( 1 {cm}^{2} ) ] / [ ( 4 ) \times ( 2.55 \times 1 {0}^{- 6} mol ) \times ( 96485 C {mol}^{- 1} ) ] = 0.04 {s}^{- 1}$$

$$TOF @ 1.51 V = [ ( 0.08 A ) \times ( 1 {cm}^{2} ) ] / [ ( 4 ) \times ( 2.55 \times 1 {0}^{- 6} mol ) \times ( 96485 C {mol}^{- 1} ) ] = 0.081 {s}^{- 1}$$

$$TOF @ 1.53 V = [ ( 0.014 A ) \times ( 1 {cm}^{2} ) ] / [ ( 4 ) \times ( 2.55 \times 1 {0}^{- 6} mol ) \times ( 96485 C {mol}^{- 1} ) ] = 0.142 {s}^{- 1}$$

$$TOF @ 1.55 V = [ ( 0.23 A ) \times ( 1 {cm}^{2} ) ] / [ ( 4 ) \times ( 2.55 \times 1 {0}^{- 6} mol ) \times ( 96485 C {mol}^{- 1} ) ] = 0.023 {s}^{- 1}$$

$$TOF @ 1.56 V = [ ( 0.34 A ) \times ( 1 {cm}^{2} ) ] / [ ( 4 ) \times ( 2.55 \times 1 {0}^{- 6} mol ) \times ( 96485 C {mol}^{- 1} ) ] = 0.035 {s}^{- 1}$$

$$TOF @ 1.58 V = [ ( 0.48 A ) \times ( 1 {cm}^{2} ) ] / [ ( 4 ) \times ( 2.55 \times 1 {0}^{- 6} mol ) \times ( 96485 C {mol}^{- 1} ) ] = 0.049 {s}^{- 1}$$

$$TOF @ 1.6 V = [ ( 0.67 A ) \times ( 1 {cm}^{2} ) ] / [ ( 4 ) \times ( 2.55 \times 1 {0}^{- 6} mol ) \times ( 96485 C {mol}^{- 1} ) ] = 0.069 {s}^{- 1}$$

$$TOF @ 1.62 V = [ ( 0.9 A ) \times ( 1 {cm}^{2} ) ] / [ ( 4 ) \times ( 2.55 \times 1 {0}^{- 6} mol ) \times ( 96485 C {mol}^{- 1} ) ] = 092 {s}^{- 1}$$

$$TOF @ 1.64 V = [ ( 0.29 A ) \times ( 1 {cm}^{2} ) ] / [ ( 4 ) \times ( 2.55 \times 1 {0}^{- 6} mol ) \times ( 96485 C {mol}^{- 1} ) ] = 1.31 {s}^{- 1}$$

### Physical and Physicochemical Investigations

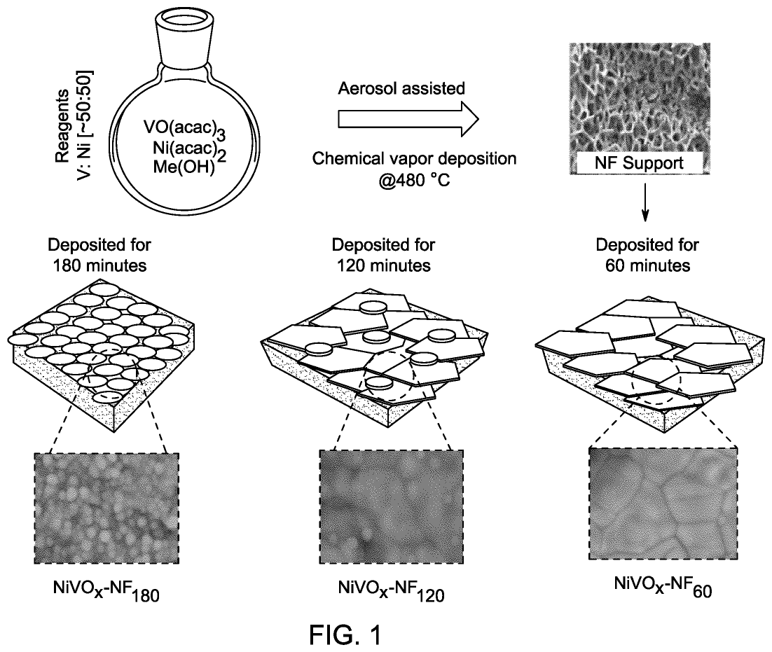

Schematic illustrations for the fabrication of NiVOx catalytic films directly grown over a conductive NF surface at 480° C. by varying the deposition time from 60 to 180 minutes, particularly at 60 minutes (NiVOx-NF₆₀), 120 minutes (NiVOx-NF₁₂₀), and 180 minutes (NiVOx-NF₁₈₀), are presented in FIG. 1. It was observed that nanoscale catalytic films with high electroactive sites were obtained by depositing catalytic precursors for a continuous 180 minutes over a conductive NF surface. Furthermore, during the scotch-tape test, it was found that the catalyst firmly adhered to the substrate. Multiple films were fabricated and confirmed the reproducibility of the AACVD technique under employed conditions. Consequently, these nanoscale catalytic films with improved conductivity and electronic structure can facilitate the adsorption/desorption process of water oxidation catalysis.

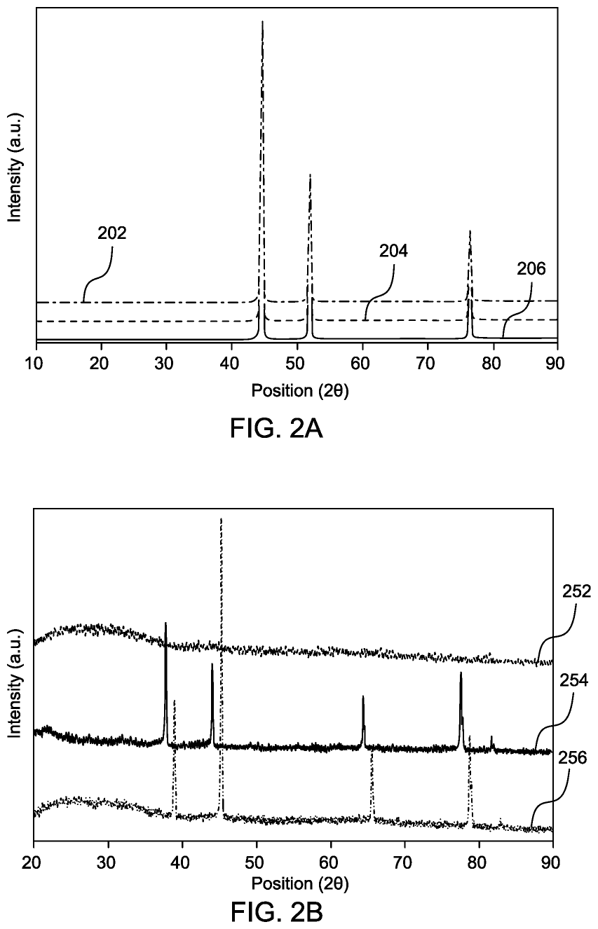

After preparation, the catalytic films were characterized to study their surface structure via X-ray diffraction pattern analysis. The XRD spectra of NiVOx film samples prepared for different periods of 60, 120, and 180 minutes on NF substrate, herein referred to as NiVOx-NF₆₀ (206), NiVOx-NF₁₂₀ (204), and NiVOx-NF₁₈₀ (202), respectively, are depicted in FIG. 2A. FIG. 2A indicates the X-ray diffraction (XRD) patterns of NiVOx films deposited on nickel foam substrates. Due to the highly crystalline nature of NF, crystalline peaks related to metallic Ni from the underlying NF substrate were only observed, and crystalline peaks from the deposited product (NiVOx) were hardly observed. Therefore, to avoid the substrate effect, the films were re-deposited on a nanocrystalline surface like a plain glass substrate, and XRD characterization was performed. FIG. 2B depicts the XRD patterns of NiVOx films deposited on glass substrates. No crystalline peak has appeared, suggesting the amorphous nature of the NiVOx product. The film sintered for 180 minutes, i.e., NiVOx-NF₁₈₀ (252) could not achieve crystallinity. However, the pristine NiO (254) and VO (256) components were crystalline.

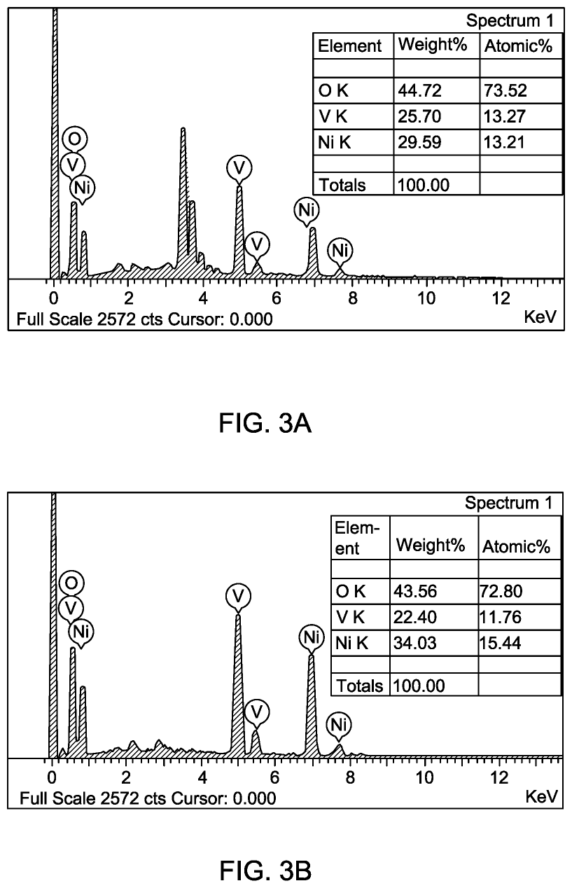

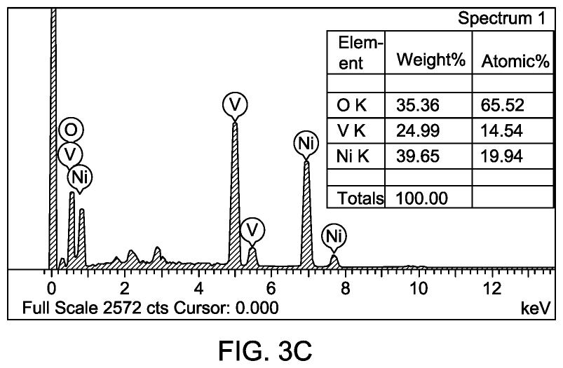

Further, the elemental composition and Ni/V metallic ratios of the as-prepared catalytic samples developed on plain glass were analyzed by energy-dispersive X-ray (EDX) spectroscopy. EDX spectra of NiVOx film samples, NiVOx-NF₆₀ (302), NiVOx-NF₁₂₀ (304), and NiVOx-NF₁₈₀ (306), prepared on plain glass substrates with measured Ni/V atomic concentrations (%) are depicted in FIG. 3. The samples were intentionally grown over the plane glass surface as film samples made on NF substrates would have a higher atomic concentration of Ni due to the contribution of nickel from the underlying foam (Ni) surface. The EDX spectra with measured elemental composition and % atomic ratios between V/Ni were found to be ˜50:50, which indicates the 1:1 mole ratio of these elements in NiVOx samples.

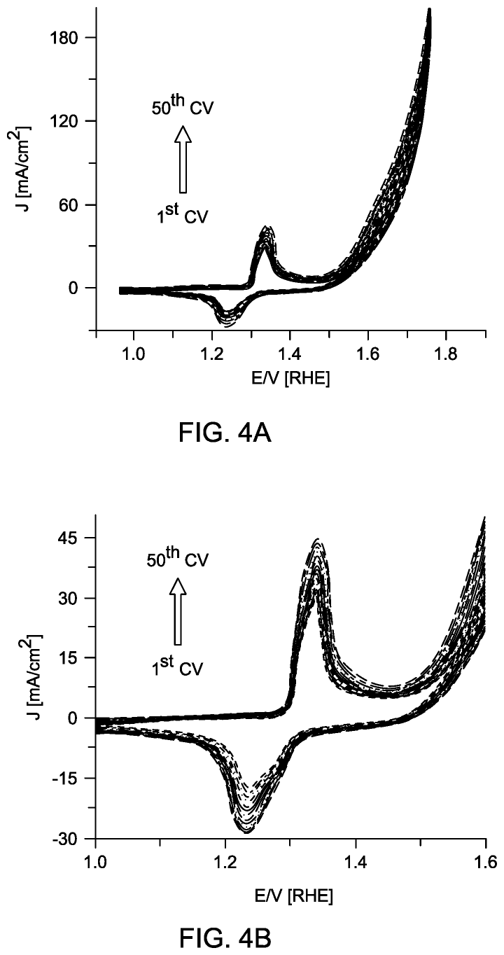

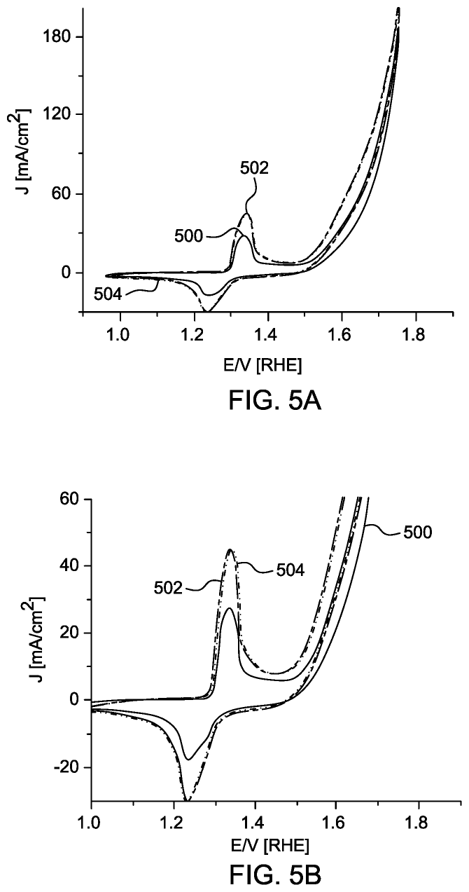

The catalysts were further tested for OER activity. For this purpose, all prepared catalysts were activated following in situ electrochemical oxidation via performing consecutive cyclic voltammetry (CV) measurements in a 1.0 M KOH solution at a scan rate of 10 mV/s before being tested for OER activity. After the in situ oxidation process, all electrodes presented much improved electrocatalytic performance due to the generation of more active components over the electrode surface and exposure of electroactive sites to the environment. In-situ oxidation of NiVOx/NF₆₀ showed a heightening in metal redox peak amplitude FIGS. 4A and 4B). Also, the onset potential for OER is shifted towards negative bias from the 1^{st} cycle (500) after the concurrent 50th cycle (502), whereas the 60th cycle (504) superimposed the 50^{th} cycle (502), as observed in FIG. 5A. An enlarged view of the FIG. 5A is depicted in FIG. 5B. OER current density was also increased.

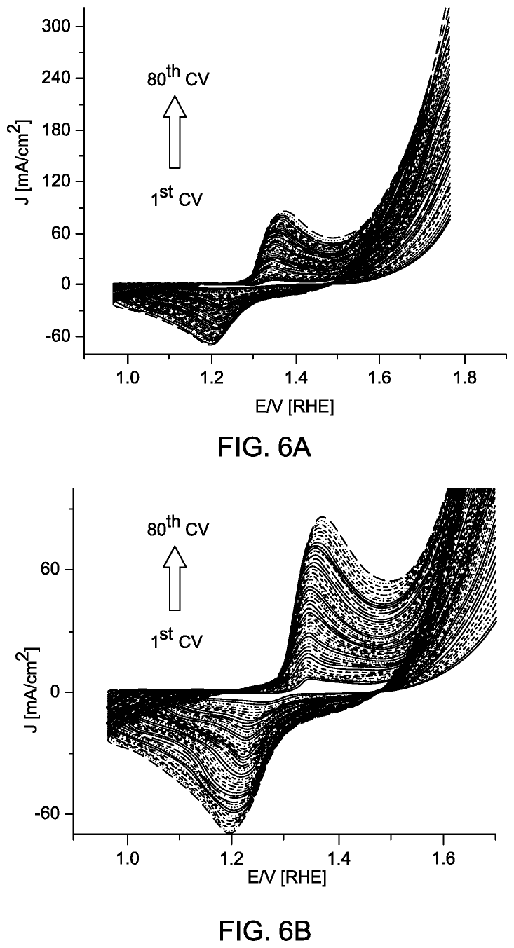

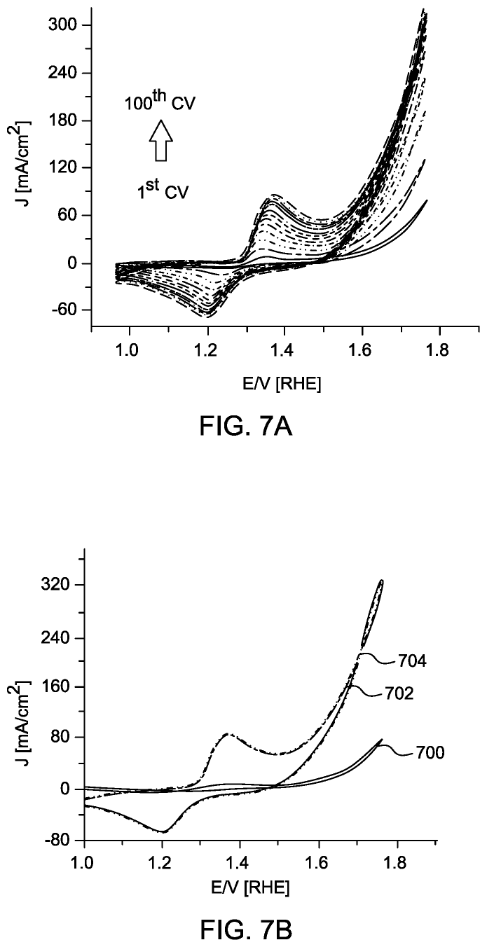

For NiVOx/NF₁₂₀, pronounced activation was observed (FIGS. 6A and 6B). Onset potential was shifted towards negative potential, and peak current density increased four-fold compared to the first CV (FIG. 6A). An enlarged view of FIG. 6A is depicted in FIG. 6B. Also, a four-fold increase in current density was observed from the 1^{st} CV (700) to the 80^{th} CV (702). The 80th CV (702) exactly overlaps the 100th CV (704) further, to which no change in redox peak amplitude and peak current density was observed (FIGS. 7A and 7B).

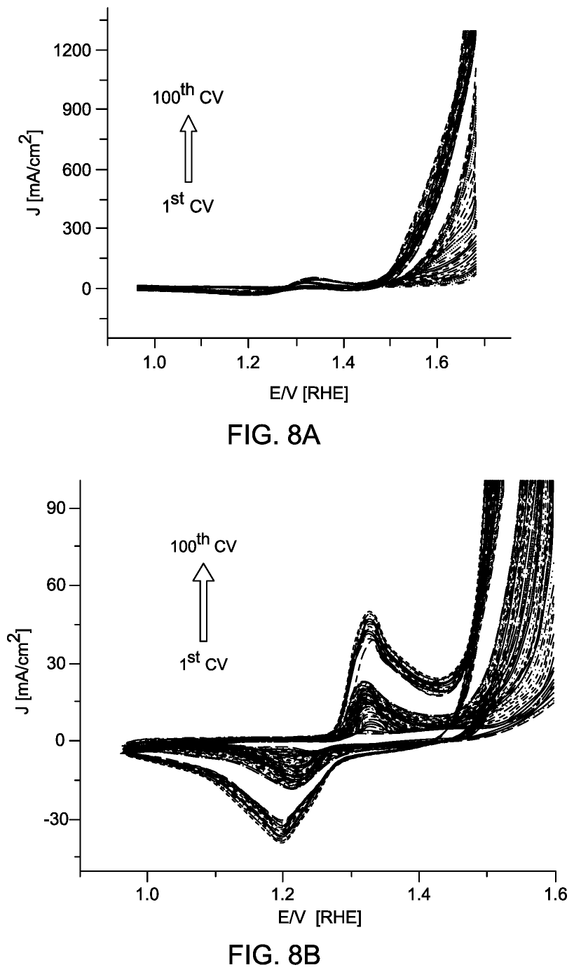

Likewise, for NiVOx/NF₁₈₀, it was illustrated that catalytic performance is continuously improving for concurrent first 40 CV cycles. A marked change in electrochemical response is observed soon after 40 CV cycles, where the 41st CV shifted towards a more negative slot. Onset potential for OER was reduced, accompanied by an enhancement in peak current as shown in FIGS. 8A and 8B. FIG. 8B is an enlarged view of FIG. 8A.

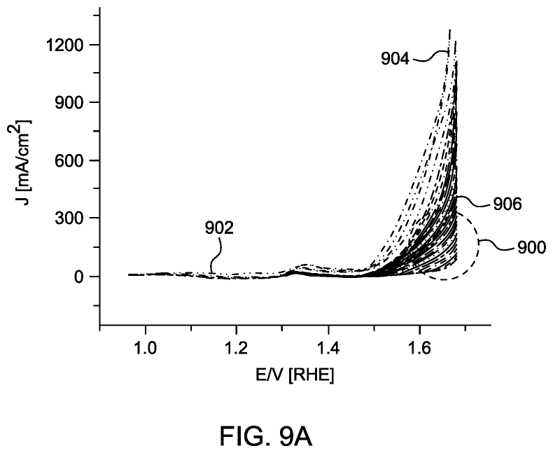

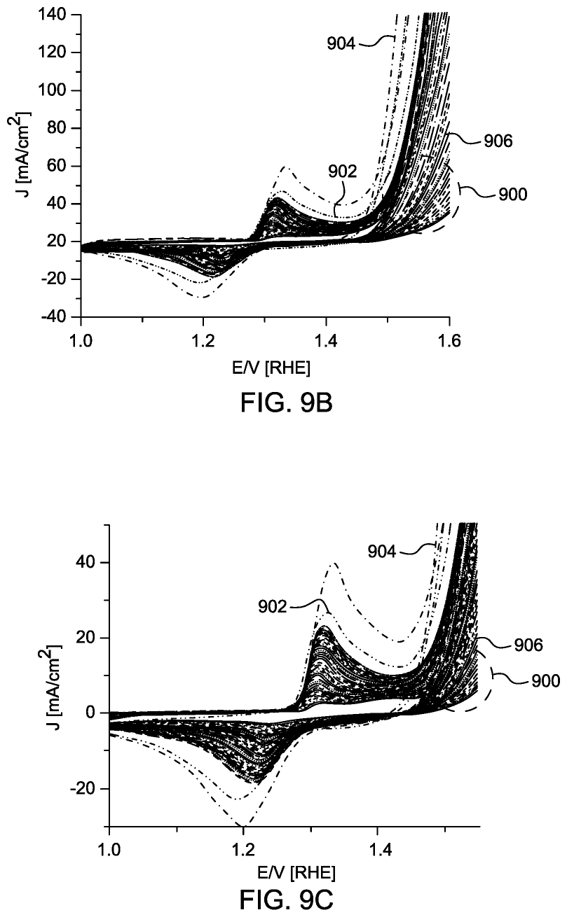

FIG. 9A shows electrocatalytic investigations-concurrent 1^{st} to 40^{th} cycle (900), 41^{st} cycle (902), 80^{th} cycle (904), and 100^{th} cycle (906) forward potential sweeps for NiVOx/NF₁₈₀ showing in-situ electrochemical activation of catalyst recorded at the scan rate of 10 mV/s in 1.0 M aq. KOH electrolyte solution. CV cycles from the 41^{st} CV (902) to the 80^{th} cycle (904) also presented some improvements in catalytic activity (FIG. 9A). An enlarged view of the FIG. 9A is depicted in FIG. 9B and 9C.

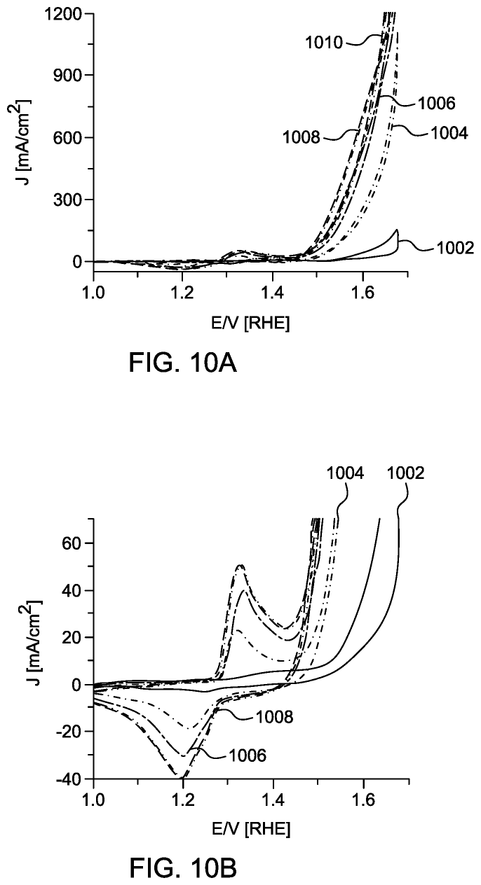

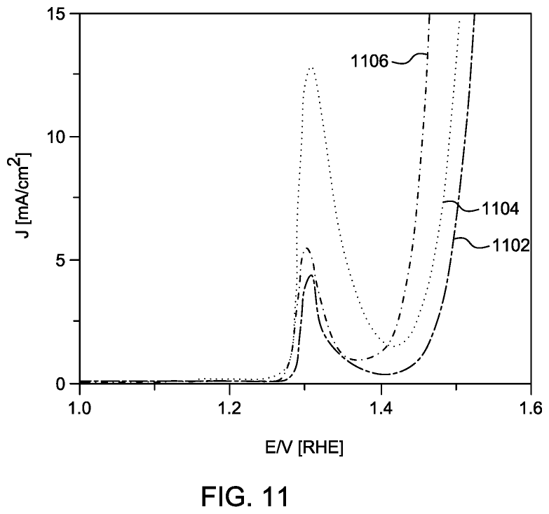

FIG. 10A is a plot depicting electrocatalytic investigations concurrent 1^{st} (1002) to 40^{th} (1004), 41^{st} (1006), 80^{th} (1008), and 100^{th} (1010) forward potential sweeps for NiVOx/NF₁₈₀ showing in-situ electrochemical activation of catalyst recorded at the scan rate of 10 mV/s in 1.0 M aq. KOH electrolyte solution. However, after the 80th CV cycle, no apparent alternation in electrochemical activity was observed where the 80th cycle (1008) overlaps the 100th CV cycle (1010), and the catalyst did not show any distinct activation and presented a somewhat similar response (FIG. 10A). An enlarged view of FIG. 10A is depicted in FIG. 10B. An enlarged view of polarization curves for NiVOx/NF₆₀ (1102), NiVOx/NF₁₂₀ (1104), and NiVOx/NF₁₈₀ (1106) was recorded at the scan rate of 2 mV/s in 1.0 M aq. KOH electrolyte solution is depicted in FIG. 11.

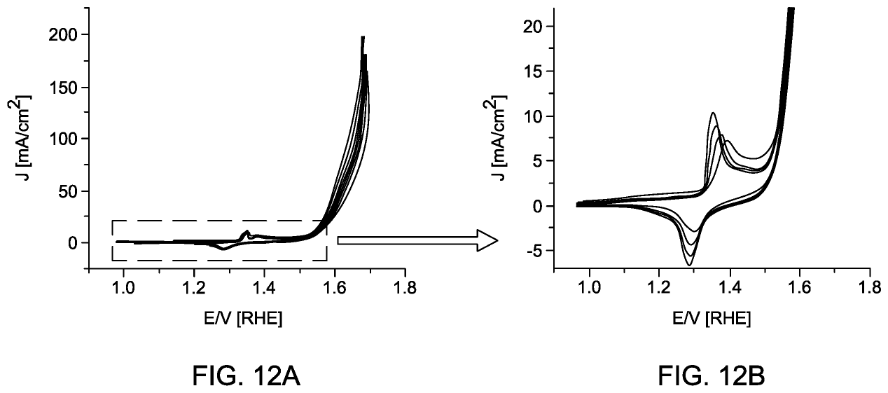

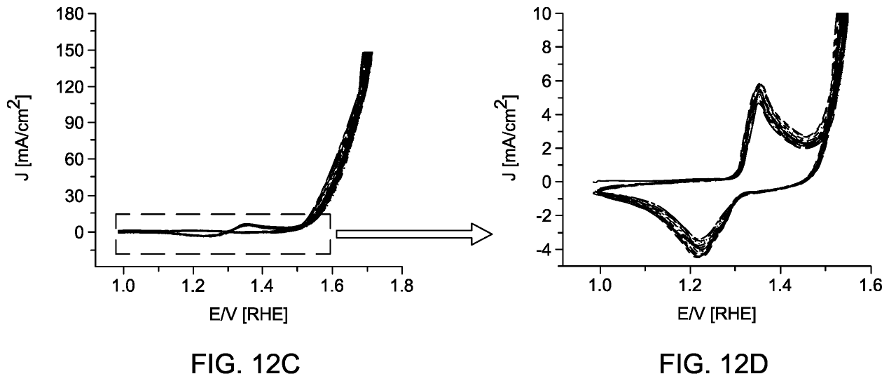

Positive potentiostat treatments electrochemically convert metal oxides into the electrochemically active component with high chemical valence, such as metal hydroxide/oxyhydroxide species, which are responsible for efficient water oxidation. The electrode films including NiVOx/NF₆₀, NiVOx/NF₁₂₀, and NiVOx/NF₁₈₀ were further tested as working electrodes for water oxidation studies. OER performance was primarily characterized via linear sweep voltammetry (LSV) measurements under a three-electrode cell configuration in a 1.0 M aq. KOH electrolyte solution with a pH of ˜14. The LSV curves for a bare NF substrate and different NiVOx catalysts deposited over NF were prepared following the single-step AACVD technique. It was observed that water oxidation initiates at an onset potential of 1.45 and 1.46 V (vs. RHE) for NiVOx/NF₆₀ and NiVOx/NF₁₂₀, respectively. However, the onset potential was shifted toward a lower bias (1.42 V vs RHE) for the NiVOx/NF₁₈₀ electrode which is fairly comparable to and even better than that of the Ru/Ir-based state-of-the-art catalyst reported previously (FIG. 12). FIG. 12A shows electrocatalytic investigations—concurrent forward potential sweeps for VOx-NF₁₈₀, and a high-resolution view of FIG. 12A is depicted in FIG. 12B. From the FIGS. 12A and 12B, it can be observed that the onset potential is shifted toward a lower bias (1.42 V vs RHE) for the NiVOx/NF₁₈₀ electrode (FIG. 12) that is fairly comparable to and even better than that of Ru/Ir-based state-of-the-art catalyst reported previously. FIG. 12C is a plot showing in-situ electrochemical activation of NiVOx-NF₁₈₀ catalysts recorded at the scan rate of 10 mV/s in 1.0 M aq. KOH electrolyte solution, while FIG. 12D depicts a high-resolution view of FIG. 12C.

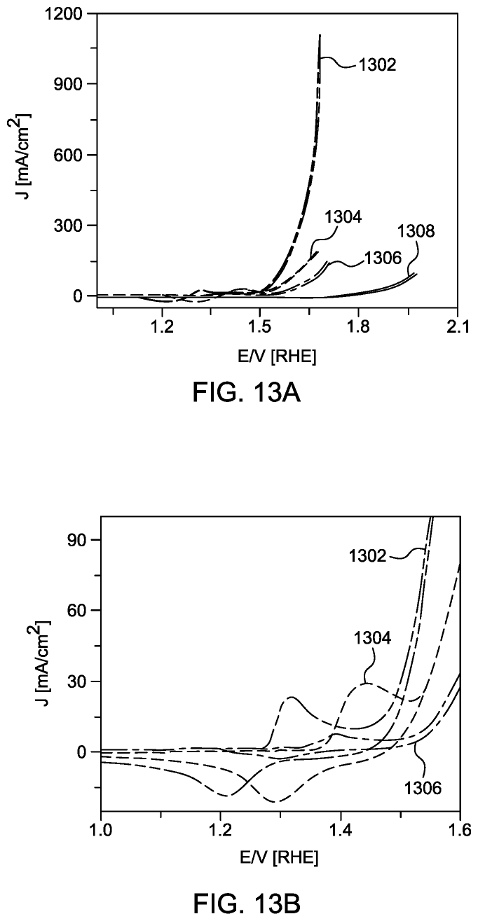

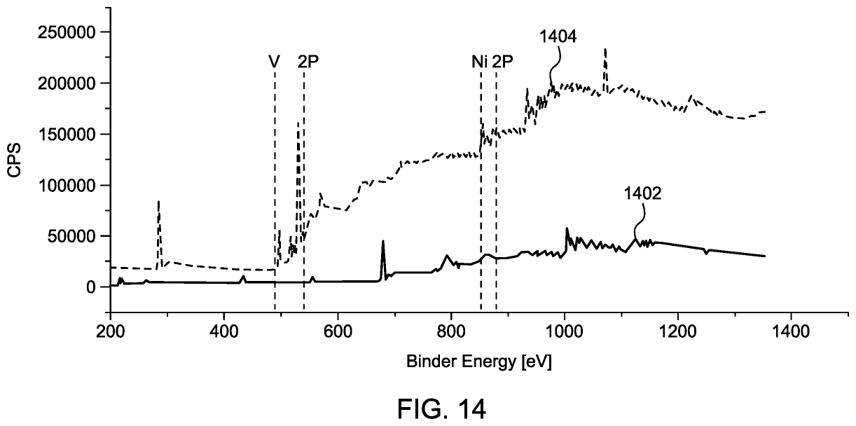

For a comparative study, monometallic oxide catalysts such as NiOx/NF and VOx/NF were also prepared (catalysts were electrochemically activated before being tested for the OER, as shown in FIGS. 13A and 13B) and investigated under similar electrochemical circumstances. The polarization curves for NiVOx/NF₁₈₀ (1302), NiOx/NF (1304), and VOx/NF (1306) bare NF substrate (1308) were recorded at the scan rate of 2 mV/s in 1.0 M aq. KOH electrolyte solution as depicted in FIG. 13A, while an enlarged view of the polarization curve is depicted in FIG. 13B.The results indicate the onset potential values of 1.48 and 1.55 V vs. RHE, respectively, for the OER (because of the appearance of large metal redox peaks, the onset potential is observed from a backward potential sweep of the CV cycle as reported previously). It was obvious that OER onset potential values are comparatively higher for monometallic catalysts, i.e., NiOx/NF₁₈₀ (1402) and VOx/NF, and shifted toward a negative value for bimetallic NiVOx/NF₁₈₀ (1404) catalysts (FIG. 14). This might be attributed to the synergistic cooperation between Ni and V metals developed over the surface of conductive and porous NF that further lower the potential input for the OER process under employed conditions.

The intrinsic catalytic behavior of a catalytic system to facilely facilitate the four-electron transfer process during a sluggish OER between the catalyst and adsorbed species can drive the reaction at a low overpotential. However, the desired adsorption-desorption of various intermediates and the rate of heterogeneous electron transfer process over the catalyst surface merely depend on the energy level of the d orbital of metal and the physicochemical properties of the substrate. Advantageously, the energy level of the d orbital of Ni oxide is comparable to that of the 2p orbital of oxygen, which facilely overlaps with the easy adsorption of hydroxyl species and subsequently releases oxygen molecules. Moreover, intrinsic catalytic behavior to initiate the OER at a much lower potential while producing high current density was further enhanced by the synergistic environment, where Ni can settle in a stable electronic environment along with V for optimum activity. Therefore, this bimetallic collaboration along with an underlying porous, conductive support was proven as the judicious selection that may realize the requisite benchmarks for a proficient OER catalyst.

To further prove this bimetallic collaboration and electronic structure modulation, XPS results of pristine NiOx (1402) and bimetallic NiVOx samples (1404) prepared under similar conditions were compared, and the results of this study are depicted in FIG. 14. It was observed that OER onset potential values were comparatively higher for monometallic catalysts, i.e., NiOx/NF and VOx/NF, and shifted toward a negative value for bimetallic NiVOx/NF catalysts (FIG. 14). This might be attributed to the synergistic cooperation between Ni and V metals developed over the surface of conductive and porous NF that further lower the potential input for the OER process under employed conditions.

The intrinsic catalytic behavior of a catalytic system was believed to facilely facilitate the four-electron transfer process during a sluggish OER between the catalyst, and adsorbed species can drive the reaction at a low overpotential. However, the desired adsorption-desorption of various intermediates and the rate of heterogeneous electron transfer process over the catalyst surface merely depend on the energy level of the d orbital of metal and the physicochemical properties of the substrate. Advantageously, the energy level of the d orbital of Ni oxide is comparable to that of the 2p orbital of oxygen, which facilely overlaps with the easy adsorption of hydroxyl species and subsequently releases oxygen molecules. Moreover, intrinsic catalytic behavior to initiate the OER at a much lower potential while producing high current density was further enhanced by the synergistic environment, where Ni can settle in a stable electronic environment along with V for optimum activity. Therefore, this bimetallic collaboration, along with an underlying porous, conductive support, was proven as the judicious selection that may realize the requisite benchmarks for a proficient OER catalyst.

To further prove this bimetallic collaboration and electronic structure modulation, XPS results of pristine NiOx (1402) and bimetallic NiVOx samples (1404), prepared under similar conditions, were compared and the results of this study are depicted in FIG. 14. It was observed that OER onset potential values were comparatively higher for monometallic catalysts, i.e., NiOx/NF and VOx/NF, and shifted toward a negative value for bimetallic NiVOx/NF catalysts (FIG. 14). This might be attributed to the synergistic cooperation between Ni and V metals developed over the surface of conductive and porous NF that further lower the potential input for the OER process under employed conditions.

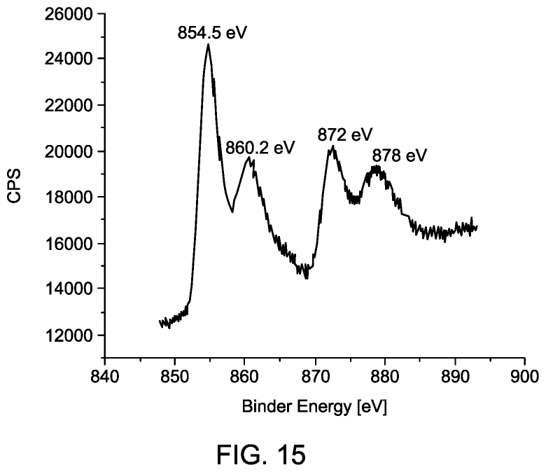

A high-resolution Ni 2p XPS spectrum of the pristine NiOx sample is depicted in FIG. 15. The survey spectrum of bimetallic NiVOx shows the appearance of the V 2p peak, which is absent in pristine NiOx. The Ni 2p spectrum of NiOx obtained via AACVD by depositing the catalyst for 180 min shows the obvious peaks that exhibit a definite shift for the bimetallic sample prepared under similar conditions showing electronic modulation of metals in a bimetallic catalyst (FIG. 15).

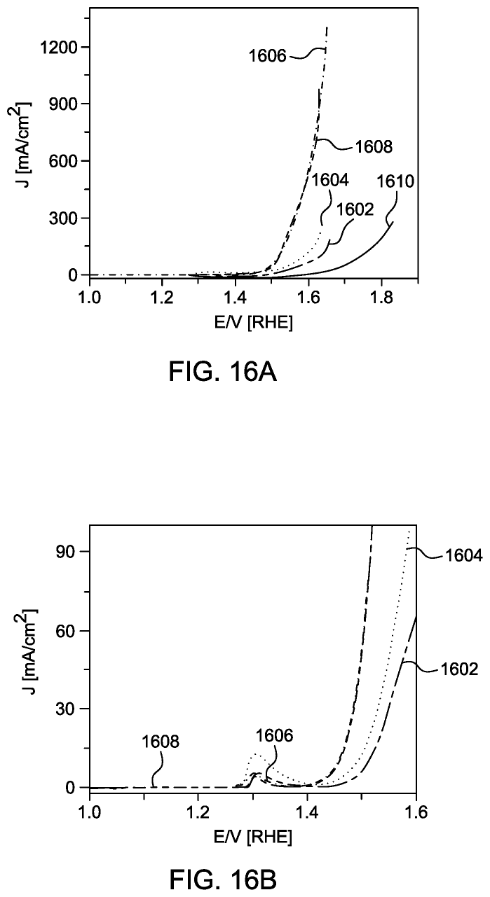

FIG. 16A shows polarization curves for NiVOx/NF₆₀ (1602), NiVOx/NF₁₂₀ (1604), NiVOx/NF₁₈₀ (1606), NiVOx/NF₂₄₀ (1608), and bare NF substrate (1610) recorded at the scan rate of 2 mV/s in 1.0 M aq. KOH electrolyte solution. FIG. 16B is an enlarged view of polarization curves depicted in FIG. 16A.

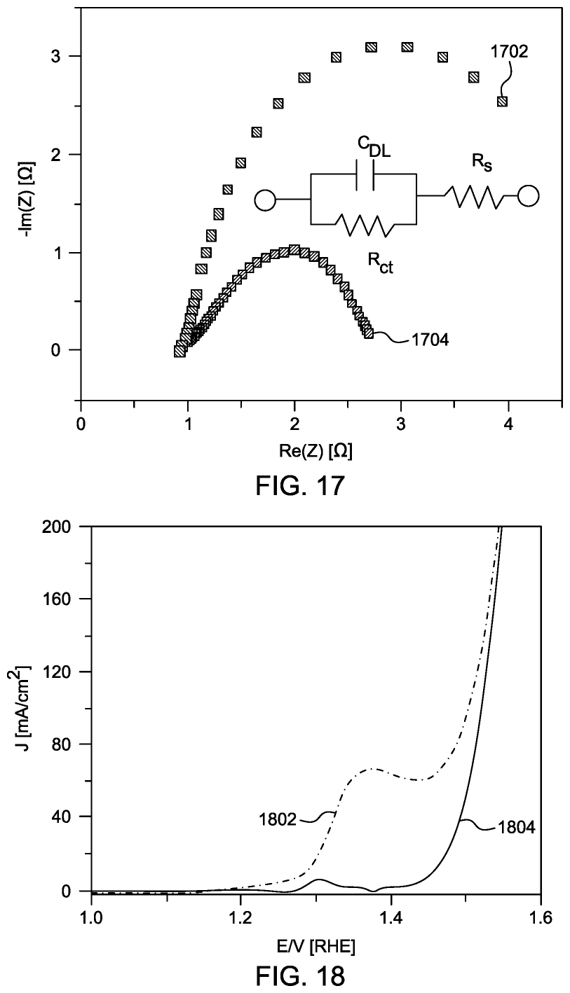

To further see the effect of an increase in the deposition time from 180 minutes (1702) on catalytic performance, catalysts were also deposited over NF for a continuous 240 minutes (1704), and comparative LSV is shown in FIG. 17. The Nyquist plots were recorded at 1.58 V vs. RHE for NiVOx/NF₁₈₀ and NiVOx/NF₂₄₀ (inset show simplifies Randles circuit diagram). NiVOx/NF₂₄₀ initiates the OER at 1.42 V vs. RH. However, the peak current density was comparatively lower than that observed for NiVOx/NF₁₈₀, which might be due to increased contact resistance between electrode/electrocatalyst as shown by a relatively high R_{ct} value of 3.4Ω. Therefore, no further investigation in the deposition time was performed higher than 240 minutes. In addition to relating the catalytic performance to nanoscale morphological features of catalytic films, the exact atomic content of participating metals was also analyzed via the inductively coupled plasma-mass spectrometry (ICP-MS) technique, and the relation with catalytic activity was elaborated. Here, NiVOx/NF₆₀, NiVOx/NF₁₂₀, and NiVOx/NF₁₈₀ show Ni and V in an atomic ratio of around 1:1, and these results were also consistent with EDX analyses (FIG. 4). It was also observed that by increasing the deposition time, the atomic concentration Ni increased to 0.78, 0.82, and 0.99 ppm for NiVOx/NF₆₀, NiVOx/NF₁₂₀, and NiVOx/NF₁₈₀ samples, respectively. However, V concentration remained almost the same for all cases with minor changes in concentration.

Correspondingly, OER catalytic activity increased with increasing deposition time as well as Ni concentration in catalytic films. However, by further increasing the deposition time to 240 min, Ni concentration was increased (0.134 ppm), and the atomic ratio of Ni and V was changed to 2:1 for Ni and V in catalytic films. Nevertheless, the catalytic activity for the sample prepared for 240 min was decreased (FIG. 17), which might be due to the saturation effect as observed previously. Therefore, it was concluded that catalytic activity of thin-film NiV catalysts prepared via AACVD at a fixed temperature depends on the atomic concentration of Ni, which increased with increasing the deposition time, and more importantly, particle morphology, size, and the film thickness. A comparative evaluation of electrocatalytic parameters and characteristics for the discussed electrocatalysts/systems observed during catalysis are presented in Table 1.

TABLE 1
Electrocatalytic characteristics for electrocatalysts

| Catalyst | | η@ 10 | η@ 100 | Peak current | Mass | |
|---|---|---|---|---|---|---|
| Onset | Overpotential | mA cm⁻² | mA cm⁻² | density | activity | R_{ct} |
| NiOx/NF | 1.48 | 1.52 | 1.61 | >170 | — | — |
| VOx/NF | 1.55 | 1.56 | 1.68 | 143 | — | — |
| RuOx/NF | 1.43 | 1.46 | 1.54 | 566 | — | — |
| NiVOx/NF₆₀ | 1.46 | 1.51 | 1.61 | >177 | 687 | 15.6 |
| NiVOx/NF₁₂₀ | 1.45 | 1.49 | 1.58 | 250 | 450 | 6.7 |
| NiVOx/NF₁₈₀ | 1.42 | 1.45 | 1.51 | 1284 | 1500 | 1.8 |
| NiVOx/NF₂₄₀ | 1.42 | 1.44 | 1.52 | 972 | — | 3.4 |

To access the durability and consistency in the catalytic performance of the NiVOx/NF₁₈₀, multistep chronoamperometry (CA) or controlled potential electrolysis (CPE) experiments were conducted. Multistep chronoamperometry curves of NiVOx/NF₁₈₀ for the OER producing high current densities under intentionally chosen narrow potential ranges from 1.40 V vs RHE to 1.84 10 V vs RHE were studied. The results indicate that at just 1.40 V vs. RHE, a stable current density of 50 mA/cm² was observed, which remained constant for the next 315 seconds. The current density readily increased to 133 mA/cm² as the potential swept to a higher value under employed conditions. Likewise, during consequent testing, a similar consistent catalytic behavior was observed, which demonstrates the high durability of the catalyst for the OER process.

Next, the kinetics of the OER was studied by turnover frequency (TOF) calculations from liner polarization curves. NiVOx/NF₁₈₀ showed a TOF of 0.48@ 1.58 V vs. RHE, which illustrates faster charge transfer kinetics of the overall electrode process. The high intrinsic activity was further ascertained by exchange current density (j_{exc}) calculations from charge transfer resistance. NiVOx/NF₁₈₀ showed a high exchange current density of 3.5 mA/cm², which demonstrates the inherent capability of catalysts to perform the OER with significantly low overpotential.

The electrochemically active surface area (ECSA) was estimated from double-layer capacitance (C_{dl}) measurements of the electrode surface. The electrochemical double-layer capacitance was evaluated via measuring non-Faradaic capacitive current directly associated with double-layer charging by undertaking CVs at different scan rates from 10 to 60 mV/s. Here, all of the measured currents are assumed to be due to double-layer charging in the non-faradaic region of the CVs. The cathodic and anodic charging currents were measured at 1.25 V vs. RHE and plotted as a function of scan rate. On averaging the absolute values of cathodic and anodic slopes of linear fittings, the double-layer capacitance was 17.8 mF, and the electrochemically active surface area (considering the specific surface area of the electrode as 0.04 cm²) was found to be 445 cm², which is significant and illustrates the substantial number of electroactive sites constituting the catalyst surface. To further study the inherent kinetics of the system, intrinsic activity (jₛ) was calculated from the electrochemically active surface area of the catalyst. The NiVOx/NF₁₈₀ showed an intrinsic activity of 1.07 mA/cm² at a potential of 1.58 V vs. RHE (η=350 mV).

Next, for evaluating the applicability of the catalyst at an industrial scale, its long-term stability was measured via an extended period of controlled current electrolysis experimentations. The time versus potential curve for NiVOx/NF₁₈₀ was studied. Stable current densities of 10 and 20 mA/cm² were selected and sustained for a prolonged period of water electrolysis experiments while monitoring the voltage response of the catalytic system at the same time to maintain high current densities. A steady potential of just 1.43 V vs RHE (η=200 mV) was preserved for a prolonged period of water electrolysis experiment at a fixed current density of just 10 mA/cm².

This is an exceptionally low potential to maintain a current decade for the water oxidation reaction. Furthermore, by stepping the current density to a higher regime, i.e., 20 mA/cm², favorably 20 mA/cm² was maintained with a mere enhancement of potential to 1.46 V vs. RHE (η=230 mV). Furthermore, there was no observable change in potential and no degradation of the catalyst over more than 20 h of continuous electrolysis. This suggests superior stability and high catalytic activity for water oxidation catalysis under employed electrochemical conditions. Thereafter, LSV was measured soon after the long-term electrolysis experiment. LSV recorded after CCE (1802) exactly overlaps with the initial polarization curve recorded before conducting the stability test (1804). However, a marked oxidation peak was initiated at 1.30 V vs. RHE and reached a maximum height at 1.35 V vs. RHE, and after undergoing a decline, it was readily followed by a water oxidation peak at about 1.42 V vs. RHE, as shown in the enlarged view of LSV (FIG. 18).

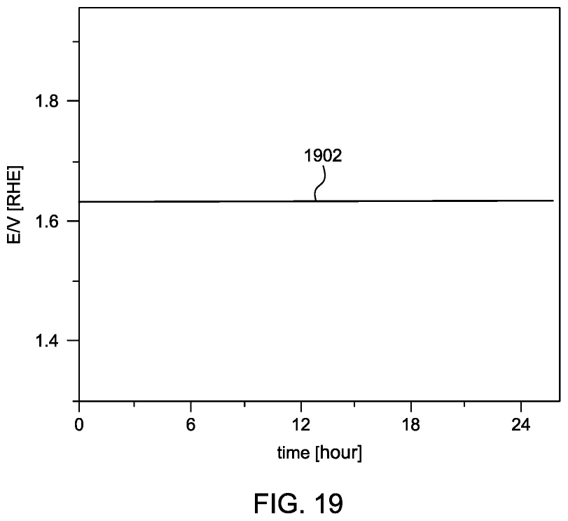

The realization of water oxidation onset soon after the metal oxidation peak also illustrated the resistance-free nature of the catalyst for the OER. This also shows the in-situ electro generation of increasingly prevalent electroactive sites over the electrode surface during long-term water electrolysis experiments. The stability of the catalyst was also evaluated by controlled current electrolysis experiments for more than 24 h at a higher current density such as 500 mA/cm² (1902), and the results are shown in FIG. 19. It has been observed that the catalyst produced a stable current at a potential of about 1.62 V vs RHE without undergoing any decline in performance. This was ascribed to the remarkable stability of catalysts for the OER under employed conditions and makes it universally applicable. Morphological, compositional, and chemical oxidational changes in the catalyst as a result of OER activity are studied by post-catalysis material characterizations. The NiVOx/NF₁₈₀ catalyst after a long-term OER study was characterized by SEM/EDX and XPS analyses.

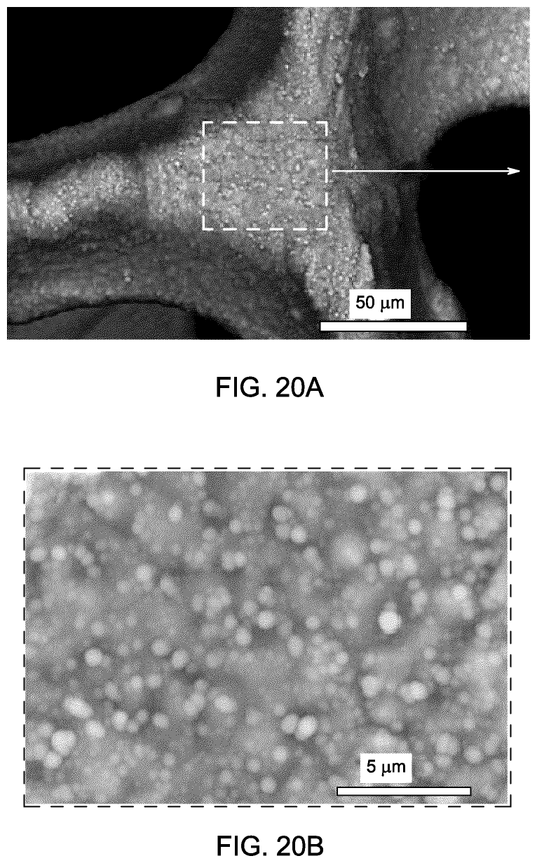

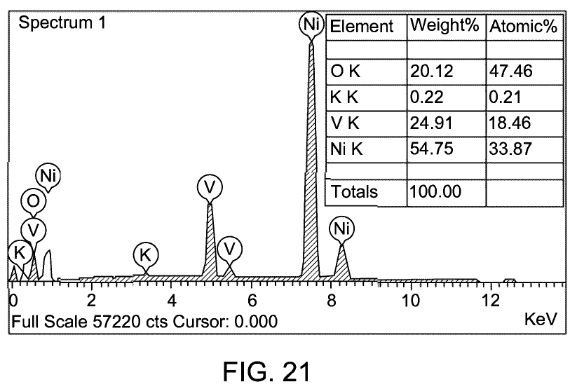

The SEM analysis (FIG. 20A and 20B) revealed that the spherical morphology and distribution of nanoparticles on the NiVOx/NF₁₈₀ electrode were not significantly altered as compared to its fresh form, presenting the morphological stability of the catalyst after an extensive OER process. Further, the Ni and V atomic contents were measured from EDX analysis of the used NiVOx/NF₁₈₀ sample (FIG. 21). The percent atomicity of Ni (33.87%) was found to be higher than that of V (18.46%). This was due to Ni atomic contribution from the NF substrate. The presence of a significant amount of elemental atomic V confirmed that both key elements (Ni and V) remain intact on the catalyst surface even after a long-term OER study. The AACVD-derived NiVOx/NF₁₈₀ directly grown on NF did not show any obvious leaching of V during vigorous OER activity. The data suggests the synthetic catalyst strategy and structure are the main parameters that need to be considered for their applicability.

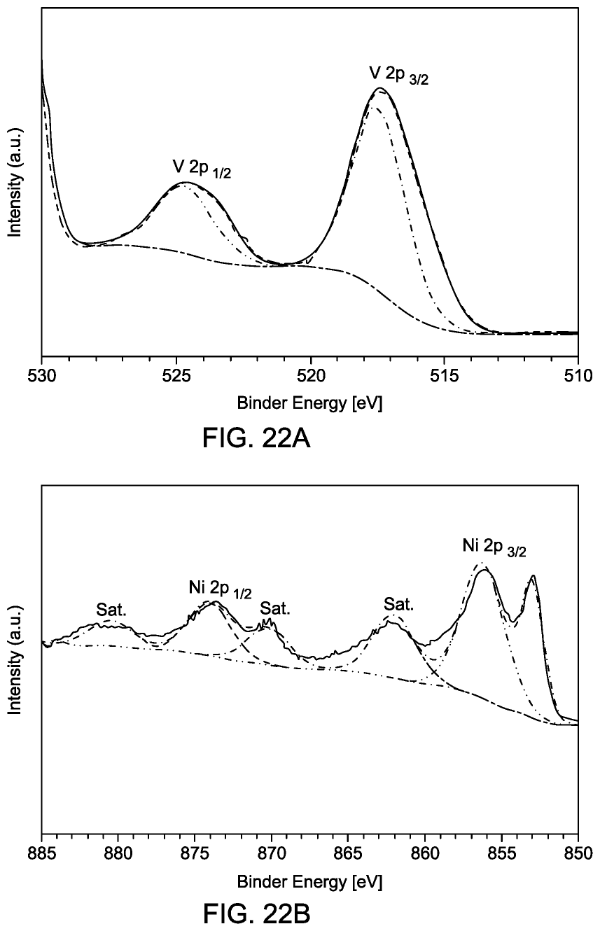

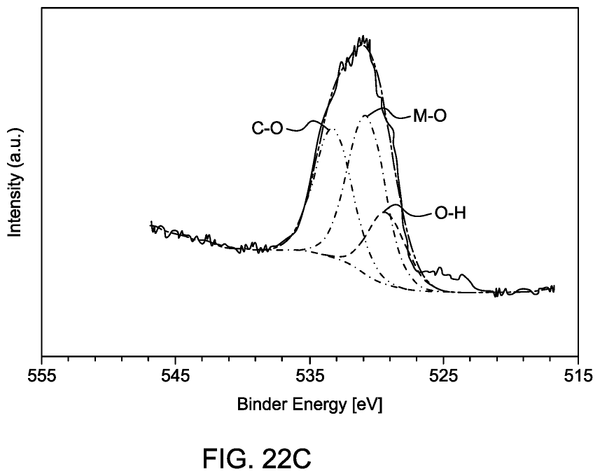

Lastly, XPS was performed to evaluate variation in the oxidation states of catalytic elements (Ni and V) after OER stability tests. XPS analysis (FIGS. 22A-22C) showed that peaks of Ni and V are characterized by a high valence state with higher binding energies after the OER. The vanadium peak at a binding energy of 517.5 eV was ascribed to V⁺⁵, suggesting that initial V⁺⁴ is oxidized to V⁺⁵ during the water oxidation reaction (FIG. 22A). Ni 2p fairly presents two primary areas due to 2p spin-orbital splitting assignable as Ni 2p 3/2 and Ni 2p½. In the Ni spectrum, a new peak located at 853.1 eV could be ascribed to Ni⁺ 3.34. The peak at 856.5 eV is also indicative of the Ni⁺³ state due to NiOOH formation during the OER. Satellite peaks at 861.5 eV (Ni 2p 3/2) and 880 eV (Ni 2p½) were consistent with Ni⁺² and Ni⁺³ showing the presence of Ni in two oxidation states and ultimate conversion into a higher oxidation state during the OER (FIG. 22B). Also, the peak area of O is enhanced (FIG. 22C).

To conclude, high-valence Ni- and V-based components were produced during the OER; therefore, both Ni and V are responsible for the excellent OER process. In addition, no mechanical flaking of the catalyst was observed from the electrode surface during long-term electrolysis experiments. Post catalysis XPS analysis suggests that high valence Ni- and V-based components were produced during the OER due to the redox reaction of both metal constituents of catalysts. Therefore, both Ni and V were responsible for the excellent electrochemical OER process. Also, it was also confirmed that the synergetic effect promoted between Ni and V is responsible for better OER the activity of bimetallic NiV oxide catalysts.

A comparative analysis of the electrochemical performance of recently reported Ni, V, and mixed Ni/V and trimetallic Ni/Fe/V-based catalysts was presented in Table 2.

TABLE 2
Electrochemical performance of catalysts

| | | | Potential | Peak current | |
|---|---|---|---|---|---|
| | | Synthesis | [mV]@10 | density | Tafel slope |
| Catalyst/system^{a} | Support | method | mA/cm² | mA/cm² | [mV dec⁻¹] |
| NiVOx/NF₁₈₀ | NF^{b} | AACVD^{c} | 210 | >1200 | 60 |
| VOx/NiS/NF | NF | hydrothermal | 330 | 300 | 121 |
| | | method | | | |
| V/NF | NF | hydrothermal | 292 | >200 | 68 |
| | | method | | | |
| VOOH | NF | hydrothermal | 270 | >120 | 68 |
| | | method | | | |
| NiO | NF | hydrothermal | 310 | 100 | 54 |
| | | method | | | |
| VOx/Ni₃S₂@NF | NF | hydrothermal | 358^{d} | 250 | 82 |
| | | method | | | |
| VOx/Ni(OH)₂@NF | NF | hydrothermal | 466^{d} | >170 | 93 |
| | | method | | | |
| Fe—V@NiO/NF₁₀ | NF | hydrothermal | 210 | 400 | 55 |
| | | method | | | |

^{a}The Ni, V, and mixed NiV catalysts are prepared by different methods and are deposited on conducting nickel foam substrates.
^{b}NF = nickel foam.
^{c}Aerosol-assisted chemical vapor deposition method.
^{d}Overpotential at 100 mA/cm².

NiVOx/NF₁₈₀ exhibited the lowest onset potential for the OER and highest peak current density relative to other highly active water oxidation systems reported in the literature. Advantageously, it was observed that the bimetallic NiVOx/NF₁₈₀ thin-film catalyst prepared by the method of the present disclosure outperforms the trimetallic Fe-V@NiO/NF₁₀ catalyst investigated under alkaline conditions. The NiVOx/NF₁₈₀-based catalytic system prepared by a straightforward AACVD method can be exploited as a cost-effective, low overpotential, and stable oxygen evolution catalyst for water oxidation to fabricate solar energy to chemical energy conversion devices.

The use of NiVOx-based catalytic materials developed over the conductive NF surface as a water oxidation catalyst was developed. Electrocatalysts were prepared via the AACVD method at various deposition times from 60 to 240 minutes. The results indicate that surface morphological features and ultimate catalytic performance of catalytic films can be facilely controlled by merely controlling the deposition time during catalyst preparation. NiVOx/NF₁₈₀ showed more substantial OER performance than other single and bimetallic catalytic systems evaluated under similar circumstances. For NiVOx/NF₆₀, NiVOx/NF₁₂₀, and NiVOx/NF₁₈₀, the oxygen evolution onset potential initiated at 1.46, 1.45, and 1.42 V (vs. RHE), respectively, while the current decade was achieved at 1.51, 1.49, and 1.44 V (vs. RHE), respectively. NiVOx/NF₁₈₀ outperformed the state-of-the-art but expensive RuO₂ catalysts when investigated under similar conditions. Moreover, a high peak current density of 1284 mA/cm² at a mere 1.64 V vs. RHE, Tafel slope of 60 mV/dec, TOF and j_{exc} of 0.48 s⁻¹@350 mV and 3.5 mA/cm², respectively, was observed for NiVOx/NF₁₈₀. Furthermore, long-term stability testing showed excellent OER performance for more than 20 h of continuous electrolysis. These results are very remarkable for easily prepared, simple water oxidation electrocatalysts.

Obviously, numerous modifications and variations of the present disclosure are possible in light of the above teachings. It is therefore to be understood that within the scope of the appended claims, the invention may be practiced otherwise than as specifically described herein.

1. (canceled)

2. The method of claim 17, wherein the first NiVOx nanostructures are in a form of overlapping NiVOx nanosheets.

3. The method of claim 2, wherein the electrocatalyst further comprises second NiVOx nanostructures comprising NiVOx nanoparticles distributed on a surface of the first NiVOx nanostructures.

4. The method of claim 3, wherein the electrocatalyst further comprises third NiVOx nanostructures in a form of NiVOx nanosheets overlapping the second NiVOx nanostructures.

5. The method of claim 17, further comprising:
heating the porous foam substrate to a deposition temperature of 250° C. to 750° C. in a reactor; and
introducing, into the reactor at the deposition temperature, an aerosol comprising a mixture of vanadyl acetylacetonate, nickel acetylacetonate, and a solvent, thereby depositing a NiVOx layer on the porous foam substrate.

6. The method of claim 5, wherein the porous foam substrate is selected from a group consisting of nickel foam and titanium foam.

7. The method of claim 5, further comprising, prior to the introducing:
aerosolizing a solution or suspension of the vanadyl acetylacetonate, the nickel acetylacetonate and the solvent to form the aerosol, wherein the solvent is at least one selected from the group consisting of isopropyl alcohol, ethanol, methanol, chloroform, dichloromethane, and dimethylsulfoxide.

8. The method of claim 5, wherein a weight ratio of vanadyl acetylacetonate and nickel acetylacetonate to the solvent in the mixture is 25:1 to 250:1.

9. The method of claim 5, wherein the mixture is introduced into the reactor while exposing the mixture to ultrasound.

10. The method of claim 5, wherein the introducing comprises flowing the aerosol with an inert gas comprising N₂, Ar, He, and/or Ne, from an aerosolization vessel to the reactor.

11. The method of claim 5, wherein the aerosol is deposited on the porous foam substrate for a deposition time of 5 to 250 minutes.

12. The method of claim 5, wherein the NiVOx layer on the porous foam substrate has an exchange current density of 1 to 6 mA/cm².

13. The method of claim 5, wherein the NiVOx layer on the porous foam substrate has a specific activity of 0.5 to 4 mA/cm².

14. The method of claim 5, wherein the NiVOx layer on the porous foam substrate has a mass activity of 100 to 2000 mA/mg.

15. The method of claim 5, wherein the NiVOx layer on the porous foam substrate has a peak current density of 100 to 1400 mA/cm².

16. The method of claim 5, wherein the NiVOx layer on the porous foam substrate has a charge transfer resistance of 0.75 to 4Ω.

17. A method of using an electrocatalyst for water oxidation, comprising:
contacting an electrocatalyst with an aqueous electrolyte solution having a pH of 8 to 14; and
applying a potential of 1.30 to 1.70 V to the electrocatalyst and a counter electrode immersed in the aqueous electrolyte solution to form oxygen and hydrogen from water in the aqueous electrolyte solution,
wherein the electrocatalyst comprises:
a porous foam substrate; and
a catalytically active layer comprising first NiVOx nanostructures, the catalytically active layer being disposed on an exterior surface and an interior pore surface of the porous foam substrate;
wherein “x” is in the range of 1 to 3.
